(19) United States
(12) Patent Application Publication
(10) Pub. No.: US 2023/0070355 A1
(43) Pub. Date: Mar. 9, 2023

(54) LAYER STRUCTURE INCLUDING METAL LAYER AND CARBON LAYER, METHOD OF MANUFACTURING THE LAYER STRUCTURE, ELECTRONIC DEVICE INCLUDING THE LAYER STRUCTURE, AND ELECTRONIC APPARATUS INCLUDING THE ELECTRONIC DEVICE

(71) Applicant: Samsung Electronics Co., Ltd., Suwon-si (KR)

(72) Inventors: Keunwook SHIN, Yongin-si (KR); Changhyun KIM, Seoul (KR); Kyung-Eun BYUN, Seongnam-si (KR)

(73) Assignee: Samsung Electronics Co., Ltd., Suwon-si (KR)

(21) Appl. No.: 17/670,912

(22) Filed: Feb. 14, 2022

(30) Foreign Application Priority Data
Sep. 8, 2021 (KR) 10-2021-0119861

(51) Int. Cl. H01L 29/49; H01L 29/40; H01L 21/28

(52) U.S. Cl. CPC H01L 29/49; H01L 29/401; H01L 21/2807

(57) ABSTRACT

Disclosed are a layer structure including a metal layer and a carbon layer, a manufacturing method the layer structure, an electronic device including the layer structure, and an electronic apparatus including the electronic device. The layer structure according to an embodiment includes an insulating layer on one surface of a semiconductor layer, a first metal layer facing the semiconductor layer with the insulating layer therebetween, a conductive first carbon layer arranged between the insulating layer and the first metal layer, the conductive first carbon layer being in contact with a first surface of the first metal layer. The first metal layer may be provided above or below the semiconductor layer. The first carbon layer may include a graphene layer. The first carbon layer may extend to another surface of the first metal layer.

### CROSS-REFERENCE TO RELATED APPLICATION

This application is based on and claims priority under 35 U.S.C. § 119 to Korean Patent Application No. 10-2021-0119861, filed on Sep. 8, 2021, in the Korean Intellectual Property Office, the disclosure of which is incorporated by reference herein in its entirety.

### BACKGROUND

### 1. Field

The present disclosure relates to electronic apparatuses, and more particularly, to layer structures including a metal layer and a carbon layer, methods of manufacturing the layer structures, electronic devices including the layer structures, and electronic apparatuses including the electronic devices.

### 2. Description of the Related Art

In the case of a semiconductor device (e.g., a field effect transistor) having a metal-oxide semiconductor (MOS) structure, a polysilicon layer is mainly used as a gate electrode. In this case, a depletion region may occur in the polysilicon layer, and an active region may be reduced due to the occurrence of the depletion region. As the size of a semiconductor device decreases as the degree of integration of the semiconductor device increases, the decrease in an active region due to the depletion region occurring in the polysilicon layer may become a practical problem in increasing the degree of integration of the semiconductor device. As a method for addressing this problem, the gate electrode has been replaced with a metal.

### SUMMARY

Provided are layer structures capable of limiting and/or preventing oxidation of a metal layer.

Provided are layer structures capable of limiting and/or preventing material diffusion from a metal layer to an insulating layer.

Provided are methods of manufacturing the layer structures.

Provided are electronic devices including the layer structures.

Provided are electronic apparatuses including the electronic devices.

Additional aspects will be set forth in part in the description which follows and, in part, will be apparent from the description, or may be learned by practice of the presented embodiments of the disclosure.

According to an embodiment, a layer structure may include an insulating layer on one surface of the semiconductor layer; a first metal layer facing the semiconductor layer with the insulating layer therebetween; and a first carbon layer between the insulating layer and the first metal layer. The first carbon layer may be in contact with a first surface of the first metal layer, and the first carbon layer may be conductive.

In some embodiments, the first metal layer may be above the semiconductor layer or below the semiconductor layer.

In some embodiments, the layer structure may further include a second metal layer on the first metal layer.

In some embodiments, the first carbon layer may extend onto a surface of the second metal layer.

In some embodiments, the first carbon layer may extend between the first metal layer and the second metal layer.

In some embodiments, the first carbon layer may cover an upper surface of the second metal layer and both side surfaces of the second metal layer.

In some embodiments, the first carbon layer may be in direct contact with the insulating layer.

In some embodiments, the first carbon layer may extend onto a second surface of the first metal layer and the second surface of the first metal layer may be different from the first surface of the first metal layer.

In some embodiments, the first carbon layer may cover a bottom surface and both side surfaces of the first metal layer.

In some embodiments, the first carbon layer may cover four sides around the first metal layer.

In some embodiments, the first carbon layer may include a sp2 bond and a sp3 bond. A ratio of sp3 bonding to sp2 bonding in the first carbon layer may be about 0 to 1.

In some embodiments, the first carbon layer may include a graphene layer. The graphene layer may include a nanocrystalline graphene layer.

In some embodiments, the first metal layer may include a one-component metal or a two-component metal.

In some embodiments, the first carbon layer may be in direct contact with the first surface of the first metal layer.

In some embodiments, a width of the first carbon layer may be equal to a width of the first metal layer.

In some embodiments, a width of the first carbon layer may be different than a width of the first metal layer.

In some embodiments, a width of the first carbon layer may be different than a width of the insulating layer.

In some embodiments, the insulating layer may surround the first metal layer.

According to an embodiment, a method of manufacturing a layer structure may include forming an insulating layer on a semiconductor layer; forming a first metal layer on the insulating layer; and forming a conductive carbon layer in contact with at least a first surface of the first metal layer. At least a portion of the conductive carbon layer may be formed between the insulating layer and the first metal layer.

In some embodiments, the forming the conductive carbon layer may include forming the conductive carbon layer using a PECVD method.

In some embodiments, the forming the conductive carbon layer may include at least one of: forming a first carbon layer in contact with a bottom surface of the first metal layer facing the insulating layer; forming a second carbon layer on a side surface of the first metal layer; and forming a third carbon layer on an upper surface of the first metal layer.

In some embodiments, the method may further include forming a second metal layer on the first metal layer.

In some embodiments, the forming the conductive carbon layer may further include forming a conductive carbon layer on an outer surface of the second metal layer.

In some embodiments, the forming the conductive carbon layer may include directly forming a graphene layer in contact with the first surface of the first metal layer; and transferring a graphene layer on the insulating layer.

In some embodiments, the graphene layer may include a nanocrystalline graphene layer.

According to an embodiment, an electronic device may include the layer structure described above. The semiconductor layer may be a substrate including a first doped region and a second doped region separated from each other. The insulating layer may be a gate insulating layer on the substrate between the first doped region and the second doped region. The first carbon layer may be on the gate insulating layer. The first metal layer may be metal gate electrode on the first carbon layer

In some embodiments, the first doped region and the second doped region may include a P-type or N-type dopant.

According to an embodiment, an electronic apparatus may include an electronic device configured to regulate the flow of an electrical signal. The electronic apparatus may include the electronic device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 23 are cross-sectional views illustrating layer structures including a metal layer and a carbon layer according to embodiments;

FIG. 24 is a graph illustrating a change in a specific resistance of a metal layer according to a thickness of a metal layer arranged on an insulating layer in a layer structure according to an embodiment;

FIG. 25 is a graph showing leakage current characteristics according to time of a layer structure according to an embodiment;

FIG. 26 is a cross-sectional view illustrating a first electronic device including a layer structure according to an embodiment;

FIGS. 27A and 27B are cross-sectional views of memory devices including a layer structure according to some embodiments;

FIG. 28 is a three-dimensional view of a second electronic device including a layer structure according to an embodiment;

FIG. 29 is a cross-sectional view taken along line 29-29′ of the second electronic device of FIG. 28;

FIG. 30 is a cross-sectional view taken along line 30-30′ of the second electronic device of FIG. 28;

FIG. 31 is a three-dimensional view illustrating a third electronic device including a layer structure according to an embodiment;

FIG. 32 is a cross-sectional view taken along line 32-32′ of the third electronic device of FIG. 31;

FIG. 33 is a cross-sectional view taken along line 33-33′ of the third electronic device of FIG. 31;

FIG. 34 is a cross-sectional view of a fourth electronic device including a layer structure according to an embodiment;

FIG. 35 is a cross-sectional view taken along line 35-35′ of the fourth electronic device of FIG. 34;

FIG. 36 is a cross-sectional view taken along line 36-36′ of the fourth electronic device of FIG. 34;

FIG. 37 is a schematic block diagram of a display driver IC (DDI) having an electronic device including a layer structure and a display device including a DDI, according to an embodiment;

FIG. 38 is a circuit diagram of a complementary metal-oxide semiconductor (CMOS) inverter equipped with an electronic device including a layer structure according to an embodiment;

FIG. 39 is a circuit diagram of a CMOS static random access memory (SRAM) device having an electronic device including a layer structure according to an embodiment;

FIG. 40 is a circuit diagram of a CMOS NAND circuit including an electronic device including a layer structure according to an embodiment;

FIG. 41 is a block diagram of an electronic system including an electronic device including a layer structure according to an embodiment;

FIG. 42 is a block diagram of an electronic system including an electronic device including a layer structure according to an embodiment; and

FIGS. 43 to 47 are cross-sectional views showing step-by-step a method of manufacturing a layer structure according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of a, b, and c” may be understood to include “only a,” “only b,” “only c,” “a and b,” “a and c,” “b and c,” or “a, b, and c”.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, layer structures including a metal layer and a carbon layer and a manufacturing method thereof, an electronic device including the layer structure, and an electronic apparatus including the electronic device, according to an embodiment will be described in detail with reference to the accompanying drawings. In the drawings, thicknesses of layers and regions may be exaggerated for clarification of the specification. The embodiments of the inventive concept are capable of various modifications and may be embodied in many different forms. When an element or layer is referred to as being “on” or “above” another element or layer, the element or layer may be directly on another element or layer or intervening elements or layers. In the descriptions below, like reference numerals refer to like elements.

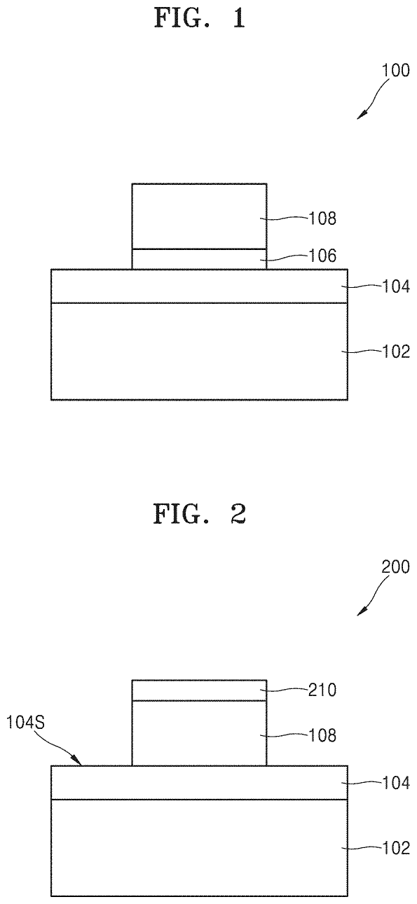

FIG. 1 shows a first layer structure 100 including a metal layer and a carbon layer according to an embodiment.

Referring to FIG. 1, the first layer structure 100 including a metal gate includes a substrate 102, an insulating layer 104 provided on the substrate 102, a carbon layer 106 on the insulating layer 104, and a first metal layer 108 on the carbon layer 106. That is, the first layer structure 100 may include a layer structure in which the substrate 102, the insulating layer 104, the carbon layer 106, and the first metal layer 108 are vertically stacked. In an example, the layer structure may be formed by sequentially stacking the material layers 102, 104, 106, and 108 in the stated order, but inventive concepts are not limited to this example. For example, as will be described later, the carbon layer 106 may be provided on the first metal layer 108. In addition, the first layer structure 100 may be provided in an upside down shape. In other words, the first metal layer 108 may be located under the substrate 102. The substrate 102 may be expressed as a base layer. The substrate 102 may include at least a semiconductor layer. In one example, the substrate 102 may include a layer structure in which an insulating layer and a semiconductor layer are sequentially stacked. In one example, the semiconductor layer may be a single layer or a multilayer. In one example, the semiconductor layer may be a semiconductor layer of one component (e.g., a Si layer, a Ge layer, etc.) or a semiconductor layer of two or more components (e.g., a GaAs layer, a GaN layer, etc.). For example, the semiconductor layer may include a non-compound semiconductor layer or a compound semiconductor layer. For example, the compound semiconductor layer may include a compound semiconductor layer (a Group III-V compound semiconductor layer) including a Group III element and a Group V element. The semiconductor layer may include a semiconductor layer doped with a conductive impurity. For example, the conductive impurity may include a P-type impurity including a Group III element or an N-type impurity including a Group V element.

The insulating layer 104 may be formed on one surface of the substrate 102. The insulating layer 104 may be arranged to cover an entire surface of the substrate 102 or may be formed on only a portion of the one surface thereof. In one example, the one surface of the substrate 102 may be a top surface, a bottom surface, or a side surface depending on the direction from which the first layer structure 100 is viewed. The insulating layer 104 may be in direct contact with the one surface of the substrate 102. In one example, a member may further be provided between the insulating layer 104 and the substrate 102, and, at this time, the substrate 102 and the insulating layer 104 may not be in direct contact. The member may be a material layer. For example, the insulating layer 104 may include a dielectric layer. For example, the insulating layer 104 may include an oxide layer or a nitride layer. For example, the insulating layer 104 may be a single layer or a multilayer. When the insulating layer 104 is a multilayer, the insulating layer 104 may include a layer structure in which insulating layers having different components are sequentially stacked or a layer structure in which insulating layers having the same components but different component ratios are sequentially stacked. The insulating layer 104 may have a thickness less than that of the substrate 102 in a direction perpendicular to the one surface of the substrate 102. For example, the thickness of the insulating layer 104 on the substrate 102 may be uniform. In one example, the insulating layer 104 may include at least one of SiO₂, SiN, HfO₂, Al₂O₃, CeO₂, ZrO₂, Y₂O₃, and La₂O₃. For example, the insulating layer 104 may correspond to a gate insulating layer of a transistor.

The carbon layer 106 may be a conductive material layer. In one example, the carbon layer 106 may be expressed as a carbon-including material layer, a carbon-including layer, or a carbon-based layer, or the like. The carbon layer 106 may exist on one surface of the insulating layer 104 and may be in direct contact with the insulating layer 104. In one example, a member may further be arranged between the carbon layer 106 and the insulating layer 104. The one surface of the insulating layer 104 may be parallel to the one surface of the substrate 102. The carbon layer 106 and the insulating layer 104 may be parallel to each other, and the insulating layer 104 and the substrate 102 may be parallel to each other. The carbon layer 106 may have a sp2 bonding structure and/or a sp3 bonding structure with respect to the first metal layer 108. For example, a ratio of sp3 bonds to sp2 bonds in the carbon layer 106 (sp3 bonds/sp2 bonds) may be in a range from about 0 to about 1. For example, the carbon layer 106 may include a graphene layer. In one example, the graphene layer may be a single layer or a multilayer. In one example, the graphene layer may include a graphene sheet. In one example, the graphene layer may include nanocrystalline graphene. For example, the nanocrystalline graphene may include crystals having a size in a range from about 0.5 nm to about 150 nm. Each of the crystals may be a domain. The carbon layer 106 may have a uniform thickness on the insulating layer 104. A water contact angle of the carbon layer 106 may be 80° or more, for example, the water contact angle may be in a range from about 80° to about 110°, but is not limited thereto. In one example, the water contact angle may be about 102°.

As described above, because the carbon layer 106 has a water contact angle indicating hydrophobic properties, the carbon layer 106 may be used as an anti-oxidation film by moisture. Accordingly, a surface of the first metal layer 108 covered with the carbon layer 106 may be protected from oxidation by moisture. In addition, because the carbon layer 106 is provided, scattering of electrons on the surface of the first metal layer 108 may be reduced, and as a result, the specific resistance of the first metal layer 108 may be improved compared to when the carbon layer 106 is not provided. This will be described later. Because the carbon layer 106 is provided, diffusion of ions from the first metal layer 108 to the insulating layer 104 may be reduced or prevented, and thus, the leakage current characteristic of the insulating layer 104 may also be improved. This will be described later.

In addition, because the carbon layer 106 is provided between the first metal layer 108 and the insulating layer 104, a work function of the first metal layer 108 may also be controlled. As will be described later, the carbon layer 106 may be arranged on at least one surface of the first metal layer 108. The first metal layer 108 may be arranged to cover the entire surface of the carbon layer 106, and may be in direct contact with one surface of the carbon layer 106. The one surface of the carbon layer 106 may be an upper surface, and may be parallel to an upper surface of the insulating layer 104. The first metal layer 108 may be a metal layer including a single component metal or an alloy layer of two or more components. In one example, the first metal layer 108 may be a metal layer including at least one of Al, Cu, Ru, Rh, Ir, Mo, W, Pd, Pt, Co, Ta, Ti, Ni, and Pd. In one example, the first metal layer 108 may be used as a metal gate electrode of a transistor.

FIG. 2 shows a second layer structure 200 including a metal layer and a carbon layer according to an embodiment. Only parts different from the first layer structure 100 of FIG. 1 will be described. The same reference numerals indicate the same members, and the descriptions thereof will be omitted. These may be equally applied to the descriptions of the drawings to be described later.

Referring to FIG. 2, in the second layer structure 200, a conductive carbon layer does not exist between the first metal layer 108 and the insulating layer 104, and the first metal layer 108 and the insulating layer 104 are in direct contact with each other. A second carbon layer 210 is provided on one surface of the first metal layer 108. The second carbon layer 210 may cover the entire surface of the first metal layer 108 and is provided to directly contact the surface. The one surface of the first metal layer 108 may be an upper surface of the first metal layer 108. The one surface of the first metal layer 108 may be parallel or substantially parallel to a bottom surface of the first metal layer 108 in direct contact with an upper surface 104S of the insulating layer 104. The second carbon layer 210 may face the insulating layer 104 with the metal layer 108 therebetween, and the second carbon layer 210 and the insulating layer 104 may be arranged parallel or substantially parallel to each other. A width of the second carbon layer 210 and a width of the metal layer 108 in a direction parallel to the upper surface 104S of the insulating layer 104 may be substantially the same. The material and layer configuration of the second carbon layer 210 may be the same as those of the carbon layer 106 of the first layer structure 100.

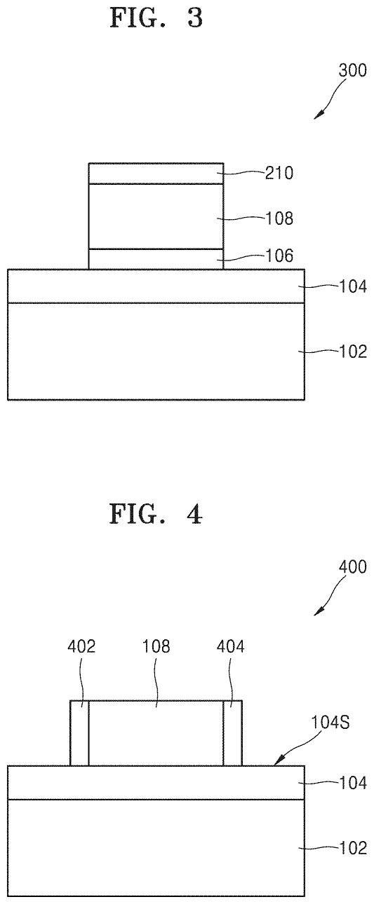

FIG. 3 shows a third layer structure 300 including a metal layer and a carbon layer according to an embodiment. Only parts different from the first layer structure 100 of FIG. 1 will be described.

Referring to FIG. 3, the third layer structure 300 may be the same as that obtained by combining the first layer structure 100 of FIG. 1 and the second layer structure 200 of FIG. 2. That is, the third layer structure 300 includes a first carbon layer 106 between the insulating layer 104 and the first metal layer 108, and a second carbon layer 210 on an upper surface of the first metal layer 108.

FIG. 4 shows a fourth layer structure 400 including a metal layer and a carbon layer according to an embodiment. Only parts different from the first layer structure 100 of FIG. 1 will be described.

Referring to FIG. 4, in the fourth layer structure 400, a bottom surface of the first metal layer 108 and the top surface 104S of the insulating layer 104 are in direct contact with each other. A left side of the first metal layer 108 may be covered with a conductive third carbon layer 402, and a right side of the first metal layer 108 may be covered with a conductive fourth carbon layer 404. The third carbon layer 402 and the fourth carbon layer 404 may be substantially parallel to each other with the first metal layer 108 therebetween. The third and fourth carbon layers 402 and 404 may have the same heights to each other, or may have the same height as the first metal layer 108. The third and fourth carbon layers 402 and 404 may have the same widths in a direction parallel to the upper surface 104S of the insulating layer 104. In one example, when both sides of the first metal layer 108 are inclined surfaces, the third and fourth carbon layers 402 and 404 may be inclined to each other. A material of the third carbon layer 402 and the fourth carbon layer 404 may be the same as that of the first carbon layer 106.

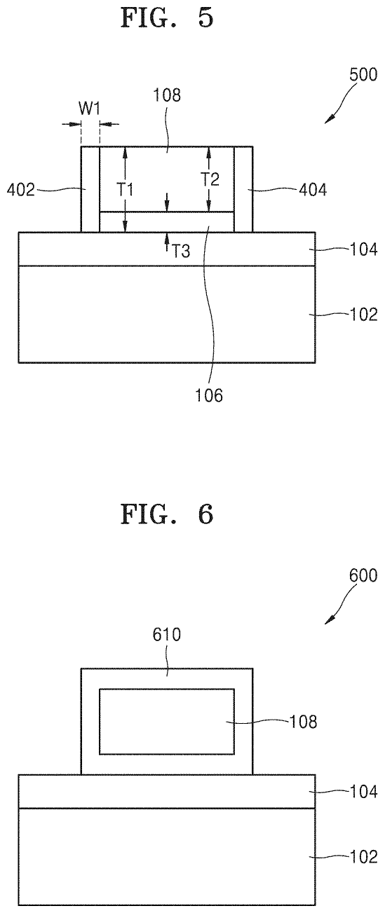

FIG. 5 shows a fifth layer structure 500 including a metal layer and a carbon layer according to an embodiment. Only portions different from the fourth layer structure 400 of FIG. 4 will be described.

Referring to FIG. 5, the fifth layer structure 500 includes a first carbon layer 106 between the first metal layer 108 and the insulating layer 104, and third and fourth carbon layers 402 and 404 are arranged on both sides of the first metal layer 108, respectively. The first carbon layer 106 is present between the third and fourth carbon layers 402 and 404, and both ends of the first carbon layer 106 are in direct contact with the third and fourth carbon layers 402 and 404. The third carbon layer 402 covers an entire left side of the first metal layer 108 and the first carbon layer 106. A thickness T1 of the third carbon layer 402 in a direction perpendicular to an upper surface of the insulating layer 104 may be greater than that of the first metal layer 108. The thickness T1 of the third carbon layer 402 may be equal to the sum of a thickness T2 of the first metal layer 108 and a thickness T3 of the first carbon layer 106. The fourth carbon layer 404 covers an entire right side of the first metal layer 108 and the first carbon layer 106. A thickness of the fourth carbon layer 404 in a direction perpendicular to the upper surface of the insulating layer 104 may be the same as the thickness T1 of the third carbon layer 402. In one example, the thickness T3 of the first carbon layer 106 may be the same as a width W1 of the third carbon layer 402 in a direction parallel to the upper surface of the insulating layer 104. Materials of the first, third and fourth carbon layers 106, 402, 404 may be the same as each other. Accordingly, the first, third, and fourth carbon layers 106, 402, and 404 may be regarded as a single carbon layer (e.g., a graphene layer) covering both sides and a bottom of the first metal layer 108.

FIG. 6 shows a sixth layer structure 600 including a metal layer and a carbon layer according to an embodiment. Only parts different from the fifth layer structure 500 of FIG. 5 will be described.

Referring to FIG. 6, the sixth layer structure 600 includes a fifth carbon layer 610 surrounding the first metal layer 108. Four surfaces of the first metal layer 108, that is, an upper surface, a lower surface, and both sides are covered with the fifth carbon layer 610. As a result, the sixth layer structure 600 may be the same as a case in which an upper surface of the first metal layer 108 is covered with a carbon layer in the fifth layer structure 500. The material of the fifth carbon layer 610 may be the same as that of the first carbon layer 106.

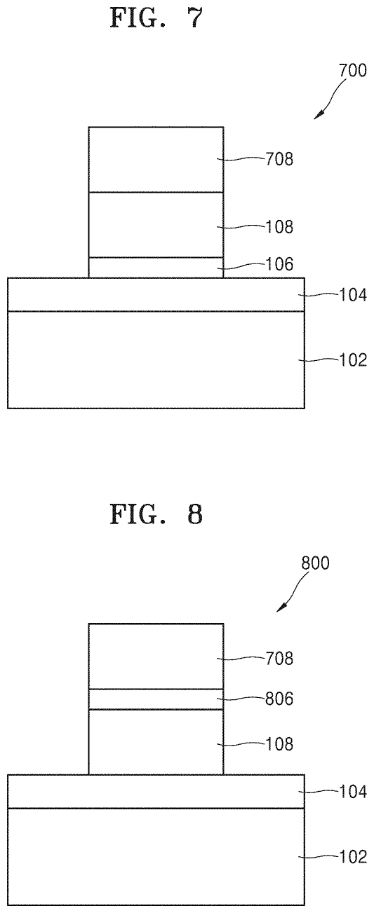

FIG. 7 shows a seventh layer structure 700 including a metal layer and a carbon layer according to an embodiment. Only parts different from the first layer structure 100 of FIG. 1 will be described.

Referring to FIG. 7, a second metal layer 708 different from the first metal layer 108 is arranged on the first metal layer 108 in the seventh layer structure 700. An entire upper surface of the first metal layer 108 may be covered with the second metal layer 708. The first and second metal layers 108 and 708 may be in direct contact with each other. As a result, the seventh layer structure 700 includes a layer structure in which the first carbon layer 106, the first metal layer 108, and the second metal layer 708 are sequentially stacked on the insulating layer 104. A width of the second metal layer 708 may be equal to a width of the first metal layer 108 in a direction parallel to the upper surface of the insulating layer 104. The thicknesses of the first and second metal layers 108 and 708 in a direction perpendicular to an upper surface of the insulating layer 104 may be the same, but may be different from each other. In one example, a material of the first metal layer 108 and a material of the second metal layer 708 may be different from each other. For example, the first metal layer 108 may include a first metal among metals shown in the description of FIG. 1, and the second metal layer 708 may include a second metal layer different from the first metal among the metals.

FIG. 8 shows an eighth layer structure 800 including a metal layer and a carbon layer according to an embodiment. Only parts different from the seventh layer structure 700 of FIG. 7 will be described.

Referring to FIG. 8, in the eighth layer structure 800, the insulating layer 104 and the first metal layer 108 are in direct contact with each other, and a sixth carbon layer 806 is arranged between the first metal layer 108 and the second metal layer 708. The material and configuration of the sixth carbon layer 806 may be the same as that of the first carbon layer 106. As a result, the eighth layer structure 800 may be the same as a case in which the first carbon layer 106 is arranged between the first metal layer 108 and the second metal layer 708 in the seventh layer structure 700.

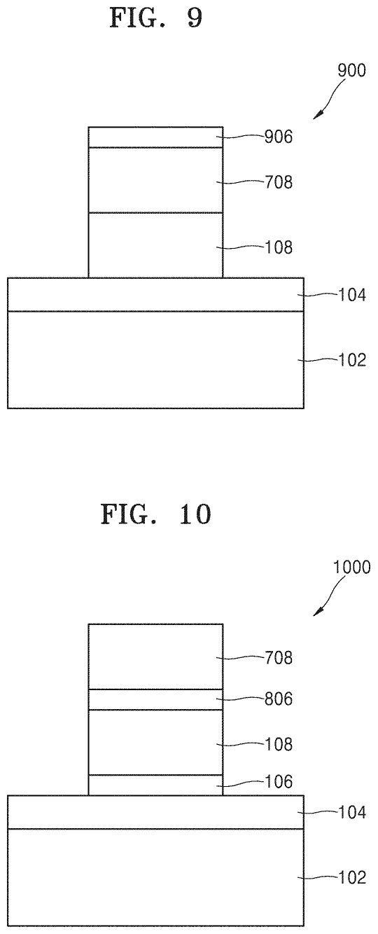

FIG. 9 shows a ninth layer structure 900 including a metal layer and a carbon layer according to an embodiment. Only parts different from the seventh layer structure 700 of FIG. 7 will be described.

Referring to FIG. 9, in the ninth layer structure 900, the insulating layer 104 and the first metal layer 108 are in direct contact with each other, and the first and second metal layers 108 and 708 are also in direct contact with each other. A seventh carbon layer 906 is arranged on the second metal layer 708. An entire upper surface of the second metal layer 708 is covered with the seventh carbon layer 906. The second metal layer 708 and the seventh carbon layer 906 are in direct contact with each other. A material of the seventh carbon layer 906 may be the same as that of the first carbon layer 106. As a result, the ninth layer structure 900 has a layer structure in which the first metal layer 108, the second metal layer 708, and the seventh carbon layer 906 are sequentially stacked on the insulating layer 104.

FIG. 10 shows a tenth layer structure 1000 including a metal layer and a carbon layer according to an embodiment. Only parts different from the seventh layer structure 700 of FIG. 7 will be described.

Referring to FIG. 10, compared to the seventh layer structure 700, the tenth layer structure 1000 further includes a sixth carbon layer 806 between the first metal layer 108 and the second metal layer 708 stacked in a direction perpendicular to an upper surface of the substrate 102. That is, the tenth layer structure 1000 includes a layer structure in which the first carbon layer 106, the first metal layer 108, the sixth carbon layer 806, and the second metal layer 708 are sequentially stacked on the insulating layer 104 including the two carbon layers 106 and 806 vertically separated from each other.

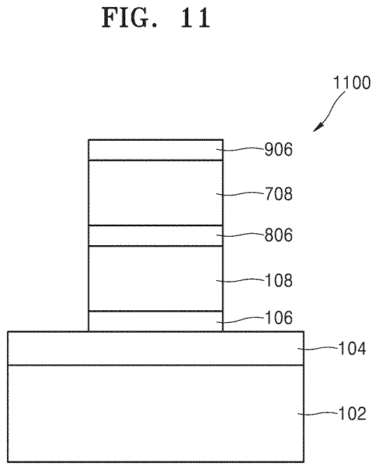

FIG. 11 shows an eleventh layer structure 1100 including a metal layer and a carbon layer according to an embodiment. Only parts different from the tenth layer structure 1000 of FIG. 10 will be described.

Referring to FIG. 11, the eleventh layer structure 1100 is a case in which a seventh carbon layer 906 is arranged on the second metal layer 708 of the tenth layer structure 1000, and includes a layer structure in which the first carbon layer 106, the first metal layer 108, the sixth carbon layer 806, the second metal layer 708, and the seventh carbon layer 906 are sequentially stacked on the insulating layer 104. As a result, the eleventh layer structure 1100 may be the same as the combination of the ninth layer structure 900 and the tenth layer structure 1000.

FIG. 12 shows a twelfth layer structure 1200 including a metal layer and a carbon layer according to an embodiment. Only parts different from the seventh layer structure 700 of FIG. 7 will be described.

Referring to FIG. 12, a carbon layer is not arranged between the insulating layer 104 and the first metal layer 108 in the twelfth layer structure 1200. Accordingly, in the twelfth layer structure 1200, the first metal layer 108 and the insulating layer 104 are in direct contact with each other. The twelfth layer structure 1200 includes an eighth carbon layer 1202 on a left side of the first metal layer 108 and a ninth carbon layer 1204 on a right side of the first metal layer 108. The eighth carbon layer 1202 may be in direct contact with a left side surface of the first metal layer 108 and may be arranged to cover an entire left side surface of the first metal layer 108. The ninth carbon layer 1204 may be in direct contact with a right side surface of the first metal layer 108 and may be arranged to cover an entire right side surface of the first metal layer 108. Heights and thicknesses of the eighth carbon layer 1202 and the ninth carbon layer 1204 in a direction perpendicular to the substrate 102 may be equal to each other. The heights of the eighth and ninth carbon layers 1202 and 1204 may be the same as the height of the first metal layer 108. Widths of the eighth and ninth carbon layers 1202 and 1204 in a direction parallel to an upper surface of the insulating layer 104 may be equal to each other. Material of the eighth and ninth carbon layers 1202 and 1204 may be the same as that of the first carbon layer 106.

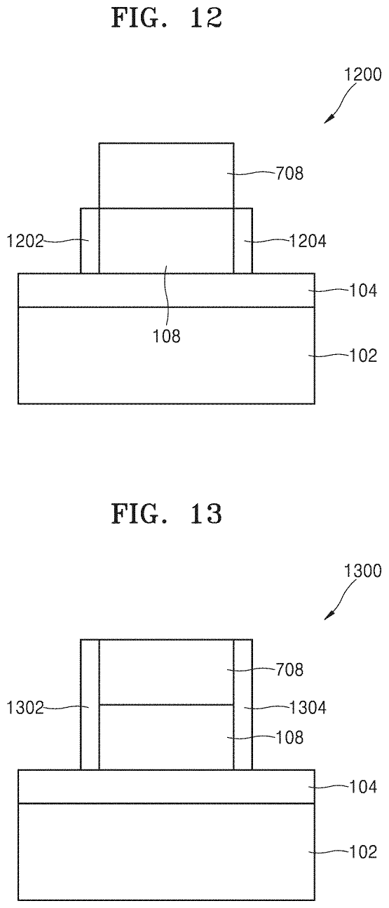

FIG. 13 shows a thirteenth layer structure 1300 including a metal layer and a carbon layer according to an embodiment. Only parts different from the twelfth layer structure 1200 of FIG. 12 will be described.

Referring to FIG. 13, the thirteenth layer structure 1300 includes a tenth carbon layer 1302 and an eleventh carbon layer 1304 on both sides of the first and second metal layers 108 and 708. The tenth and eleventh carbon layers 1302 and 1304 are arranged on the insulating layer 104, and lower ends thereof are in contact with the insulating layer 104. The tenth carbon layer 1302 may be formed to cover entire left side surfaces of the first and second metal layers 108 and 708. The tenth carbon layer 1302 may be in direct contact with the left side surfaces of the first and second metal layers 108 and 708. The eleventh carbon layer 1304 may be formed to cover entire right side surfaces of the first and second metal layers 108 and 708, and may be in direct contact with the right side surfaces thereof. Heights of the tenth and eleventh carbon layers 1302 and 1304 may be equal to that of the second metal layer 708. Upper surfaces of the tenth and eleventh carbon layers 1302 and 1304 may form the same plane as an upper surface of the second metal layer 708. Thicknesses of the tenth and eleventh carbon layers 1302 and 1304 in a direction perpendicular to the substrate 102 may be equal to each other. The thicknesses of the tenth and eleventh carbon layers 1302 and 1304 may be equal to the sum of the thickness of the first metal layer 108 and the thickness of the second metal layer 708. Widths of the tenth and eleventh carbon layers 1302 and 1304 in a direction parallel to the substrate 102 may be equal to each other. Material of the tenth and eleventh carbon layers 1302 and 1304 may be the same as that of the first carbon layer 106.

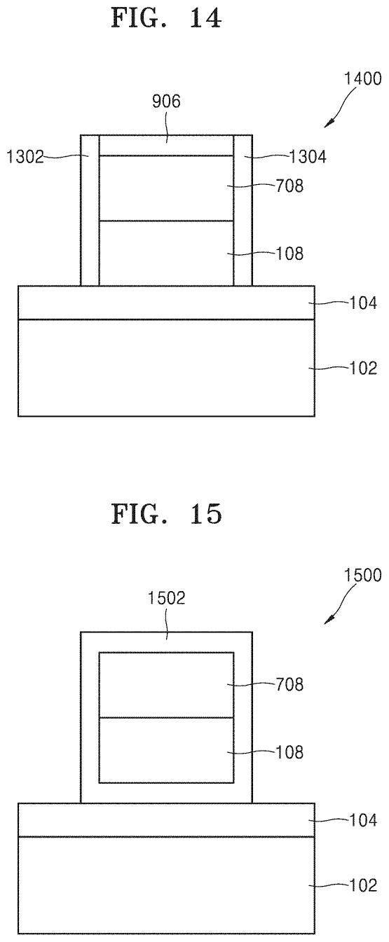

FIG. 14 shows a fourteenth layer structure 1400 including a metal layer and a carbon layer according to an example embodiment. Only parts different from the thirteenth layer structure 1300 of FIG. 13 will be described.

Referring to FIG. 14, the fourteenth layer structure 1400 is a case in which a seventh carbon layer 906 is arranged on an upper surface of the second metal layer 708 of the thirteenth layer structure 1300. As a result, the fourteenth layer structure 1400 may be the same as the combination of the ninth layer structure 900 and the thirteenth layer structure 1300. The seventh carbon layer 906 arranged on the upper surface of the second metal layer 708 may cover the entire upper surface of the second metal layer 708 and may be in direct contact with the upper surface of the second metal layer 708. The seventh carbon layer 906 may be in direct contact with the tenth and eleventh carbon layers 1302 and 1304. A left side surface of the seventh carbon layer 906 may be covered by the tenth carbon layer 1302, and a right side surface may be covered by the eleventh carbon layer 1304. A height of an upper surface of the seventh carbon layer 906 may be the same as the heights of the tenth and eleventh carbon layers 1302 and 1304. The upper surface of the seventh carbon layer 906 and upper surfaces of the tenth and eleventh carbon layers 1302 and 1304 may form the same plane. A thickness of the seventh carbon layer 906 in a direction perpendicular to an upper surface of the substrate 102 and widths of the tenth and eleventh carbon layers 1302 and 1304 in a direction parallel to the upper surface of the substrate 102 may be the same. In one example, when the seventh, tenth, and eleventh carbon layers 906, 1302, and 1304 are the same material layer, the seventh, tenth, and eleventh carbon layers 906, 1302, and 1304 may form a single carbon layer. This is a case in which both side surfaces of the first metal layer 108 and both side surfaces and an upper surface of the second metal layer 708 are covered with the single carbon layer.

FIG. 15 shows a fifteenth layer structure 1500 including a metal layer and a carbon layer according to an embodiment. Only parts different from the fourteenth layer structure 1400 of FIG. 14 will be described.

Referring to FIG. 15, an entire outer surface of the metal stack 108+708 including the first and second metal layers 108 and 708 sequentially stacked in the fifteenth layer structure 1500, that is, a bottom and both side surfaces of the 108 and both side surfaces and an upper surface of the second metal layer 708 are covered with a twelfth carbon layer 1502. A material of the twelfth carbon layer 1502 may be the same as that of the first carbon layer 106. A thickness of the twelfth carbon layer 1502 around the metal stack 108+708 may be substantially uniform.

As a result, the fifteenth layer structure 1500 may be the same as a case in which the tenth carbon layer 1302 or the eleventh carbon layer 1304 is extended between the insulating layer 104 and the first metal layer 108 in the fourteenth layer structure 1400.

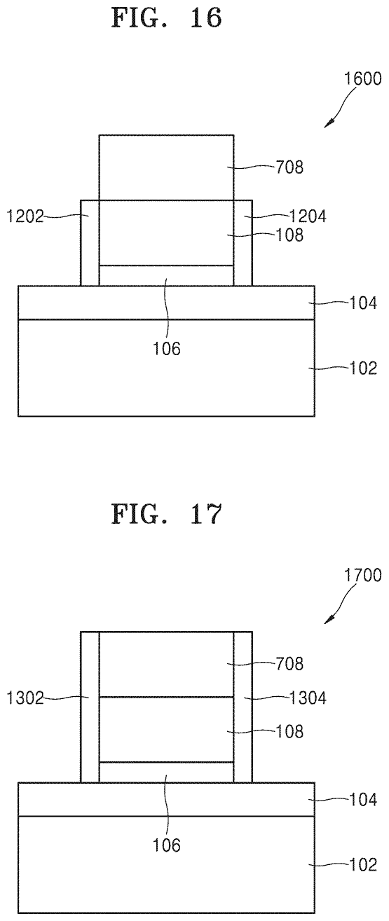

FIG. 16 shows a sixteenth layer structure 1600 including a metal layer and a carbon layer according to an example embodiment. Only parts different from the twelfth layer structure 1200 of FIG. 12 will be described.

Referring to FIG. 16, the sixteenth layer structure 1600 includes the first carbon layer 106 between the insulating layer 104 and the first metal layer 108. The rest of the sixteenth layer structure 1600 may be the same as the twelfth layer structure 1200. As a result, the sixteenth layer structure 1600 may be the same as a case in which the eighth carbon layer 1202 or the ninth carbon layer 1204 extends between the insulating layer 104 and the first metal layer 108 in the twelfth layer structure 1200.

FIG. 17 shows a seventeenth layer structure 1700 including a metal layer and a carbon layer according to an embodiment. Only parts different from the thirteenth layer structure 1300 of FIG. 13 will be described.

Referring to FIG. 17, the seventeenth layer structure 1700 includes the first carbon layer 106 between the insulating layer 104 and the first metal layer 108. The rest of the seventeenth layer structure 1700 may be the same as the thirteenth layer structure 1300. As a result, the seventeenth layer structure 1700 may be the same as a case in which the tenth carbon layer 1302 or the eleventh carbon layer 1304 extends between the insulating layer 104 and the first metal layer 108 in the thirteenth layer structure 1300.

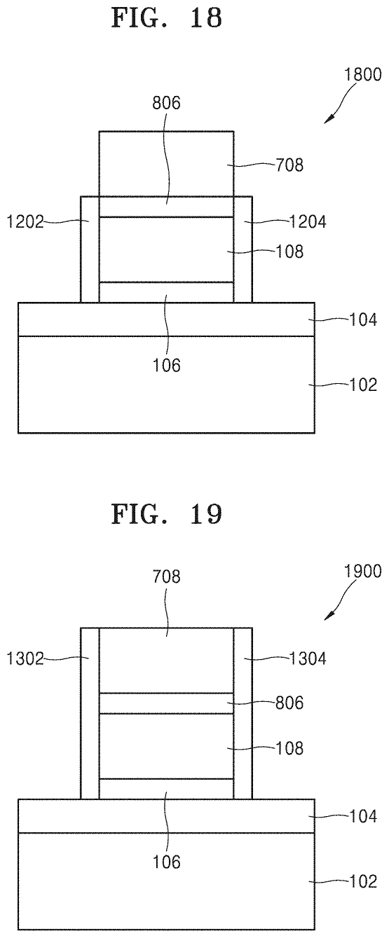

FIG. 18 shows an eighteenth layer structure 1800 including a metal layer and a carbon layer according to an embodiment. Only portions different from the sixteenth layer structure 1600 of FIG. 16 will be described.

Referring to FIG. 18, the eighteenth layer structure 1800 includes the sixth carbon layer 806 between the first metal layer 108 and the second metal layer 708 that are sequentially stacked. The rest may be the same as the sixteenth layer structure 1600. As a result, the eighteenth layer structure 1800 may be the same as a case in which the eighteenth carbon layer 1202 or the ninth carbon layer 1204 extends between the first metal layer 108 and the second metal layer 708 in the sixteenth layer structure 1600. A left side surface of the sixth carbon layer 806 is covered with the eighth carbon layer 1202, and a right side surface is covered with the ninth carbon layer 1204. Upper surfaces of the eighth and ninth carbon layers 1202 and 1204 and an upper surface of the sixth carbon layer 806 may form the same plane. In one example, the sixth carbon layer 806 and the eighth and ninth carbon layers 1202 and 1204 may be the same material, in this case, the first metal layer 108 is surrounded by a single carbon layer. That is, the upper surface, the bottom surface, and both side surfaces of the first metal layer 108 may be covered with the single carbon layer.

FIG. 19 shows a nineteenth layer structure 1900 including a metal layer and a carbon layer according to an embodiment. Only portions different from the eighteenth layer structure 1800 of FIG. 18 will be described.

Referring to FIG. 19, both side surfaces of the second metal layer 708 in the nineteenth layer structure 1900 are covered with the tenth and eleventh carbon layers 1302 and 1304, respectively. The rest may be the same as the eighteenth layer structure 1800. Consequently, the nineteenth layer structure 1900 may be the same as a case in which the tenth and eleventh carbon layers 1302 and 1304 in the eighteenth layer structure 1800 extend onto both side surfaces of the second metal layer 708. Upper surfaces of the tenth and eleventh carbon layers 1302 and 1304 and an upper surface of the second metal layer 708 may form the same plane.

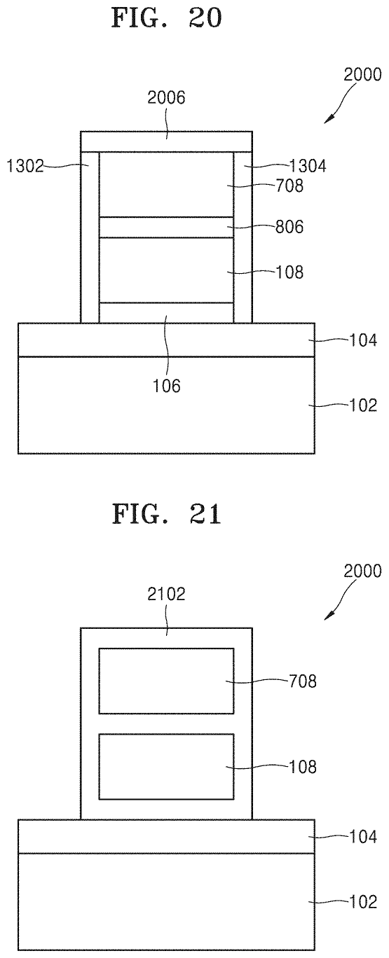

FIG. 20 shows a twentieth layer structure 2000 including a metal layer and a carbon layer according to an embodiment. Only parts different from the nineteenth layer structure 1900 of FIG. 19 will be described.

Referring to FIG. 20, the twentieth layer structure 2000 includes a thirteenth carbon layer 2006 on the second metal layer 708. The thirteenth carbon layer 2006 may cover an entire upper surface of the second metal layer 708 and entire upper surfaces of the tenth and eleventh carbon layers 1302 and 1304, and may be in direct contact with each of the upper surfaces. The twentieth layer structure 2000 may be the same as a case in which the tenth carbon layer 1302 or the eleventh carbon layer 1304 extends onto the second metal layer 708 in the nineteenth layer structure 1900. In one example, the first carbon layer 106, the sixth carbon layer 806, the tenth carbon layer 1302, the eleventh carbon layer 1304, and the thirteenth carbon layer 2006 may be the same carbon material layer. In this case, an around of the first metal layer 108 and the second metal layer 708 is surrounded by a single carbon layer. That is, the upper, bottom and both side surfaces of the first metal layer 108 and the upper, bottom, and both side surfaces of the second metal layer 708 may be covered with one fourteenth carbon layer 2102 as shown in FIG. 21.

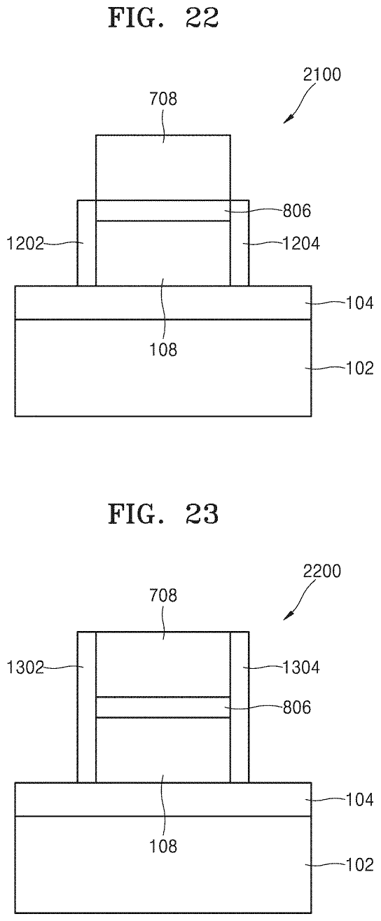

FIG. 22 shows a twenty-first layer structure 2100 including a metal layer and a carbon layer according to an embodiment. Only parts different from the twelfth layer structure 1200 of FIG. 12 will be described.

Referring to FIG. 22, the twenty-first layer structure 2100 includes the sixth carbon layer 806 arranged between the first metal layer 108 and the second metal layer 708. The remaining configuration may be the same as that of the twelfth layer structure 1200.

The sixth carbon layer 806 may cover an entire upper surface of the first metal layer 108 and an entire bottom surface of the second metal layer 708, and may be in direct contact with the upper surface of the first metal layer 108 and the bottom surface of the second metal layer 708. Both side surfaces of the sixth carbon layer 806 may be covered with eighth and ninth carbon layers 1202 and 1204, respectively. The sixth carbon layer 806, the eighth carbon layer 1202, and the ninth carbon layer 1204 may be the same carbon material layer. As a result, the twenty-first layer structure 2100 may be the same as a case in which the eighth carbon layer 1202 or the ninth carbon layer 1204 extends between the first metal layer 108 and the second metal layer 708 in the twelfth layer structure 1200.

FIG. 23 shows a twenty-second layer structure 2200 including a metal layer and a carbon layer according to an embodiment. Only parts different from the thirteenth layer structure 1300 of FIG. 13 will be described.

Referring to FIG. 23, the twenty-second layer structure 2200 includes the sixth carbon layer 806 arranged between the first metal layer 108 and the second metal layer 708. The remaining configuration may be the same as that of the thirteenth layer structure 1300.

The sixth carbon layer 806 covers the entire upper surface of the first metal layer 108 and the entire bottom surface of the second metal layer 708. The sixth carbon layer 806 may be in direct contact with the upper surface of the first metal layer 108 and the bottom surface of the second metal layer 708. Both sides of the sixth carbon layer 806 may be covered with the tenth and eleventh carbon layers 1302 and 1304, respectively. The sixth carbon layer 806, the tenth carbon layer 1302, and the eleventh carbon layer 1304 may be the same carbon material layer. As a result, the twenty-second layered structure 2200 may be the same as a case in which the tenth carbon layer 1302 or the eleventh carbon layer 1304 extends between the first metal layer 108 and the second metal layer 708 in the thirteenth layered structure 1300.

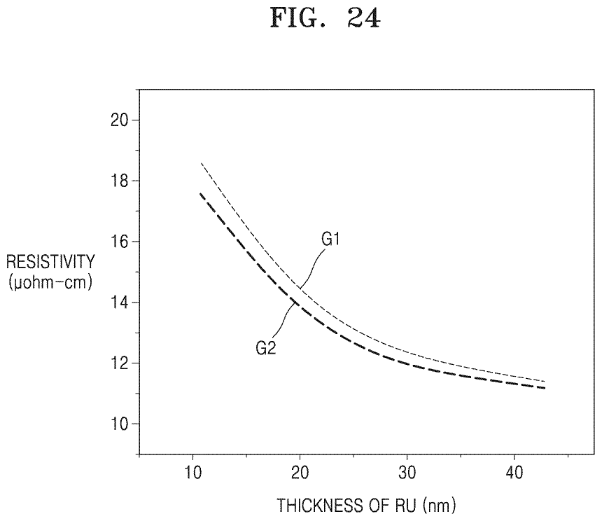

FIG. 24 shows a change in specific resistance of a metal layer according to the thickness of the metal layer arranged on the insulating layer 104 in a layer structure according to an embodiment.

In FIG. 24, the horizontal axis represents a thickness of the metal layer, and the vertical axis represents a resistance. The first graph G1 shows the result for a first case in which only the metal layer is provided without the carbon layer, that is, the result for the existing layer structure. The second graph G2 shows a result for a second case in which the metal layer is arranged together with a carbon layer, that is, the result for the layer structure according to an embodiment. In the layer structure used to obtain the result shown in FIG. 24, ruthenium (Ru) selected from the metals listed above was used as the metal layer, and graphene was used as the carbon layer.

Referring to the first and second graphs G1 and G2, in both the first and second cases, as the thickness of the metal layer increases, the specific resistance decreases. However, it may be seen that the specific resistance in the second case is less than the specific resistance in the first case. That is, when the thickness of the metal layer is the same, the specific resistance of the second case is less than that of the first case. These results suggest that, by arranging the carbon layer on a surface of the metal layer, electron scattering on the surface of the metal layer is relatively reduced compared to when the carbon layer is not arranged. In other words, the result of FIG. 24 suggests that, because the carbon layer is arranged on the surface of the metal layer, a current flowing through the metal layer may be increased than when the carbon layer is not arranged.

The metal layer may be used as a metal gate electrode, and the result of FIG. 24 may show a characteristic of a transistor including a carbon layer on one surface of the metal gate electrode.

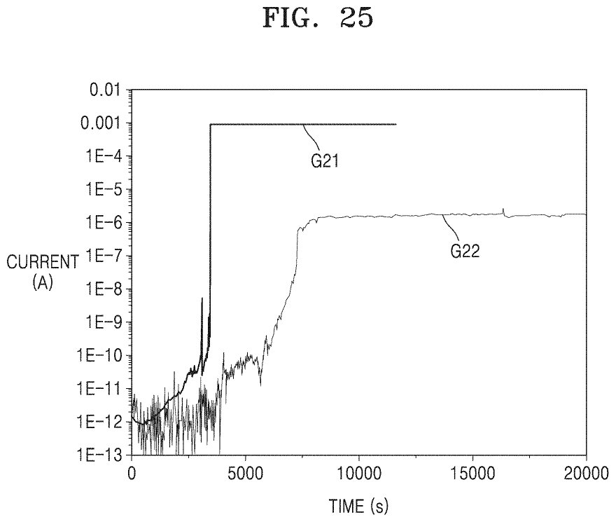

FIG. 25 shows a leakage current characteristic with time of a layer structure according to an embodiment. In FIG. 25, the horizontal axis represents time (seconds), and the vertical axis represents current (A). A first graph G21 shows a result for a first case in which only the metal layer is arranged, that is, the result for the existing layer structure. A second graph G22 shows a result for a second case in which the carbon layer is arranged on one surface of the metal layer together with the metal layer, that is, the result for the layer structure according to an embodiment.

Referring to the first and second graphs G21 and G22, a current in the second case G22 is less than a current in the first case G21, and this result is continuously maintained during the measurement time. The result of FIG. 24 suggests that, because the carbon layer is arranged on one surface of the metal layer, a leakage current through the insulating layer 104 is less than when the carbon layer is not arranged. This shows that because a carbon layer is arranged on one surface of the metal layer, a leakage current characteristic may be improved. One of the causes of a leakage current breakdown (leakage current increase) of the insulating layer 104 is diffusion of a material (e.g., ions) from the metal layer to the insulating layer 104. From the result of FIG. 24, it may be seen that, because the carbon layer is arranged on one surface of the metal layer, the material that diffuses from the metal layer to the insulating layer 104 is reduced. As a result, it may be seen that the carbon layer arranged on one surface of the metal layer performs a role of limiting and/or preventing a material that weakens the leakage current characteristic of the insulating layer 104 from being diffused into the insulating layer 104.

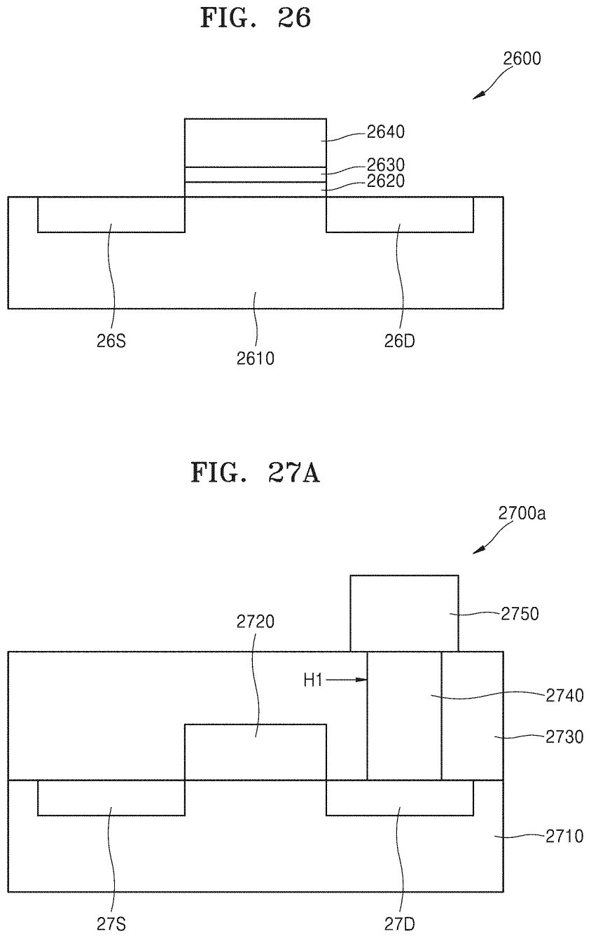

FIG. 26 shows a first electronic device 2600 including a layer structure according to an embodiment. The first electronic device 2600 may include a field effect transistor.

Referring to FIG. 26, the first electronic device 2600 may include a substrate 2610 having first and second doped regions 26S and 26D separated from each other, a gate insulating layer 2620 arranged on the substrate 2610 between the first and second doped regions 26S and 26D, a carbon layer 2630 arranged on the gate insulating layer 2620, and a gate electrode 2640 arranged on the carbon layer 2630. The substrate 2610 may include a semiconductor substrate doped with at least a first type impurity, and the first and second doped regions 26S and 26D may be provided on the semiconductor substrate. In an example, the substrate 2610 may be a P-type semiconductor substrate or an N-type semiconductor substrate doped with a P-type or N-type conductive impurity as the first-type impurity. A non-semiconductor layer may further be arranged under the semiconductor substrate. In an example, the non-semiconductor layer may include an insulating layer.

The first and second doped regions 26S and 26D may be regions doped with a second type impurity. The second type impurity may be an impurity opposite to the first type impurity. For example, when the first type impurity is a P-type conductive impurity, the second type impurity may be an N-type conductive impurity. One of the first and second doped regions 26S and 26D may be a source region, and the other may be a drain region. The gate insulating layer 2620 is formed on an upper surface of the substrate 2610 between the first and second doped regions 26S and 26D, covers an entire upper surface, and may be in direct contact with the upper surface. The substrate 2610 under the gate insulating layer 2620 may provide a channel between the first and second doped regions 26S and 26D. When the first electronic device 2600 is operated, carriers may move between the first and second doped regions 26S and 26D through the channel. The carrier may include electrons or holes. The gate insulating layer 2620 may be in contact with the first and second doped regions 26S and 26D. The gate insulating layer 2620 may be a single layer or a multilayer. The gate insulating layer 2620 may extend over a portion of the first and second doped regions 26S and 26D. In one example, a material of the gate insulating layer 2620 may be the same as the material of the insulating layer 104 described with reference to FIG. 1, but is not limited thereto. The carbon layer 2630 may cover an entire upper surface of the gate insulating layer 2620 and may be in direct contact with the upper surface of the gate insulating layer 2620. A material of the carbon layer 2630 may be the same as that of the carbon layer 106 described with reference to FIG. 1, but is not limited thereto. The gate electrode 2640 may be arranged to cover an entire upper surface of the carbon layer 2630. The upper surface of the carbon layer 2630 may be a surface facing the gate electrode 2640. A surface of the carbon layer 2630 facing the gate electrode 2640 may directly contact the gate electrode 2640. In one example, the carbon layer 2630 may be arranged on the other surface of the gate electrode 2640 and may extend on the other surface of the gate electrode 2640. In one example, the gate electrode 2640 may be an electrode layer including a metal, that is, a metal gate electrode or may include a metal gate electrode. The material of the gate electrode 2640 may be the same as the material of the first metal layer 108 described with reference to FIG. 1, but is not limited thereto.

Considering the materials of the substrate 2610, the gate insulating layer 2620, the carbon layer 2630, and the gate electrode 2640, a layer structure including the substrate 2610, the gate insulating layer 2620, the carbon layer 2630, and the gate electrode 2640 may correspond to one of the layer structures according to the embodiments described above. The gate insulating layer 2620, the carbon layer 2630, and the gate electrode 2640 may be collectively referred to as a gate stack. The expression “gate stack” is not intended to limit the position of the carbon layer 2630 between the gate electrode 2640 and the gate insulating layer 2620. The expression “gate stack” may include a case in which the carbon layer 2630 is arranged on the other surface of the gate electrode 2640. The carbon layer 2630 in the first electronic device 2600 may be expressed in consideration of roles (e.g., an oxidation prevention layer, a diffusion prevention layer). The carbon layer 2630 may have a thickness capable of exhibiting an optimal effect as the functional carbon layer 2630.

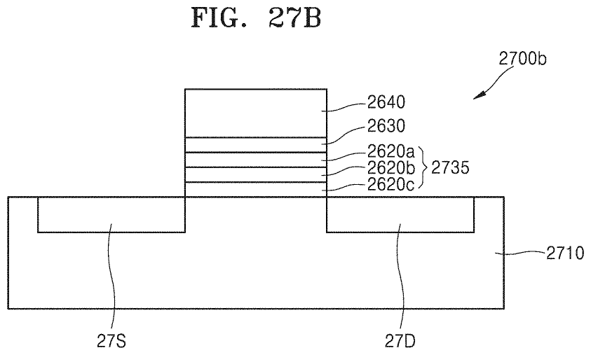

FIG. 27A shows a memory device 2700a including a layer structure according to an embodiment.

Referring to FIG. 27A, the memory device 2700a includes a substrate 2710, first and second doped regions 27S and 27D on the substrate 2710, a gate stack 2720 on the substrate 2710 between the first and second doped regions 27S and 27D, and a data storage element 2750 connected to the second doped region 27D. The substrate 2710 may correspond to the substrate 2610 of FIG. 26. The first and second doped regions 27S and 27D may correspond to the first and second doped regions 26S and 26D of FIG. 26. The gate stack 2720 may correspond to the gate stack described with reference to FIG. 26. An interlayer insulating layer 2730 covering the first and second doped regions 27S and 27D and the gate stack 2720 is formed on the substrate 2710. The interlayer insulating layer 2730 includes a via hole H1 exposing a portion of the second doped region 26D. The via hole H1 is filled with a conductive plug 2740. The conductive plug 2740 covers an entire exposed portion of the second doped region 27D. The data storage element 2750 may be arranged on the interlayer insulating layer 2730, cover an upper surface of the conductive plug 2740, and may be in direct contact with the upper surface. The data storage element 2750 may include memory cells arranged in storage nodes of various memory devices. For example, data storage element 2750 may include one of memory cells arranged in one of a storage node of DRAM, a storage node of FRAM, a storage node of SRAM, a storage node of MRAM, and a storage node of PRAM, but the data storage element 2750 is not limited thereto. The memory cell may include a configuration capable of storing data ‘1’ or ‘0’. For example, the memory cell may include a capacitor or a magnetic tunnel junction (MTJ).

FIG. 27B shows a memory device 2700b including a layer structure according to an embodiment.

Referring to FIG. 27B, the memory device 2700b may be the same as the first electronic device 2600 described in FIG. 26, except the gate insulating layer 2735 may include a multi-layer structure including a charge trap layer. The memory device 2700b may configured as a charge-trapping memory device based on programming or discharging electric charge onto the charge trap layer.

The gate insulating layer 2735 may include a first insulating layer 2620c on a portion of the substrate between the first and second doped regions 27S and 27D, a second insulating layer 2620b on the first insulating layer 2620c, and a third insulating layer 2620a on the second insulating layer 2620b. The third insulating layer 2620a may directly contact a bottom surface of the carbon layer 2630. The first insulating layer 2620c may directly contact an upper surface of the substrate 2710. The first insulating layer 2620c and the third insulating layer 2620a may include a same insulating material, such as silicon oxide, and the second insulating layer 2620b may include a different insulating material, such as silicon nitride or hafnium oxide or aluminum oxide. The first insulating layer 2620c and the third insulating layer 2620a may be serve as a tunnel insulation layer and a blocking insulation layer, respectively. The second insulating layer 2620b may serve as a charge trap layer.

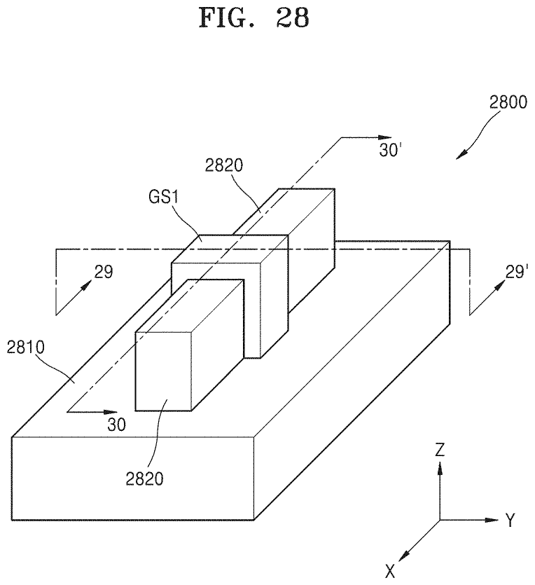

FIG. 28 shows a second electronic device 2800 including a layer structure according to an embodiment. The second electronic device 2800 may include a FinFET.

Referring to FIG. 28, a semiconductor layer 2820 is aligned in a first direction on the substrate 2810. A gate stack GS1 is arranged on a partial region of the semiconductor layer 2820. The gate stack GS1 may be arranged to cover a portion of an upper surface and a portion of both side surfaces of the semiconductor layer 2820. The substrate 2810 may be an insulating substrate. In one example, the substrate 2810 may be a substrate including an insulating layer on one surface on which the semiconductor layer 2820 and the gate stack GS1 are formed. The one surface may be an upper surface of the substrate 2810. The first direction may be parallel to the one surface of the substrate 2810 or an X-axis. The semiconductor layer 2820 may include a P-type or N-type semiconductor layer. The semiconductor layer 2820 may correspond to a semiconductor layer included in the substrate 102 described with reference to FIG. 1. One of a left portion and a right portion of the semiconductor layer 2820 with respect to the gate stack GS1 may be a source or a source electrode, and the remaining portion may be a drain or a drain electrode. Each of the semiconductor layer 2820 and the gate stack GS1 may have an aspect ratio greater than 1 (e.g., greater than 1 and less than or equal to 5), but is not limited thereto. In one example, a height of each of the semiconductor layer 2820 and the gate stack GS1 in a Z-axis direction may be greater than, equal to, or less than a width in a Y-axis direction. The height of the gate stack GS1 may be greater than the height of the semiconductor layer 2820.

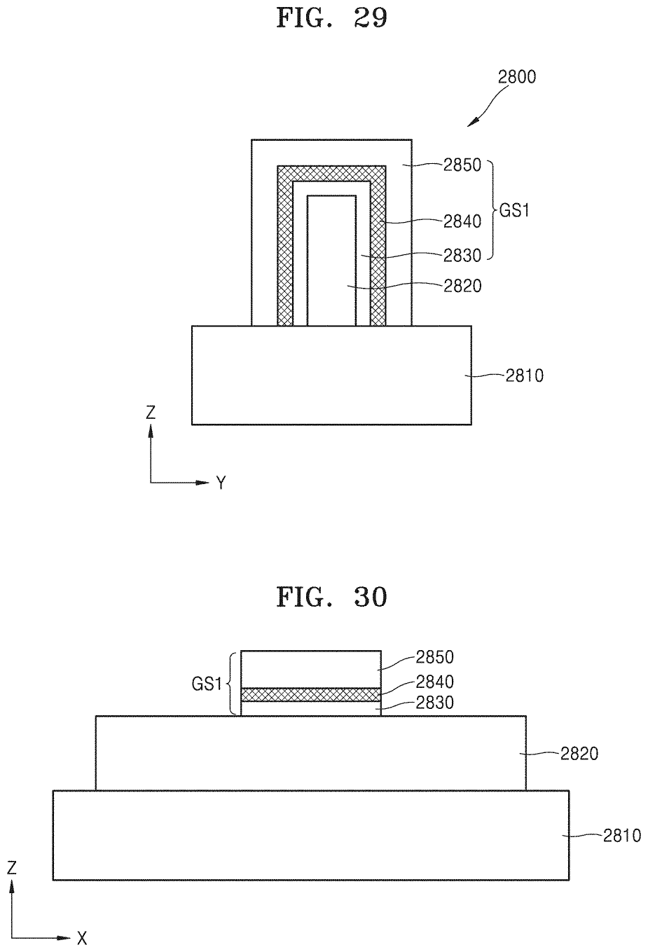

FIG. 29 is a cross-sectional view taken along line 29-29′ of FIG. 28.

Referring to FIG. 29, the semiconductor layer 2820 is formed on the substrate 2810. An aspect ratio of the semiconductor layer 2820 may be greater than 1 (e.g., greater than 1 and less than or equal to 5), but may be 1 or less than 1. A surface of the semiconductor layer 2820 may be a channel layer.

Both side surfaces and an upper surface of the semiconductor layer 2820 are covered with a gate insulating layer 2830. A thickness of the gate insulating layer 2830 formed on the semiconductor layer 2820 may be constant or substantially constant. The thickness of the gate insulating layer 2830 may be less than that of the semiconductor layer 2820. A conductive carbon layer 2840 and a gate electrode 2850 are sequentially stacked on side and upper surfaces of the gate insulating layer 2830. The carbon layer 2840 may correspond to the carbon layer 106 described with reference to FIGS. 1 to 23. Accordingly, the material and role of the carbon layer 2840 may be the same as that of the carbon layer 106. In one example, the gate electrode 2850 may correspond to the first metal layer 108 described with reference to FIGS. 1 to 23. In one example, the gate electrode 2850 may correspond to a metal stack including the sequentially stacked first and second metal layers 108 and 708 described in the layer structure according to the embodiment. In one example, a carbon layer may also be present on an outer surface of the gate electrode 2850. For example, an entire upper surface and an entire side surfaces of the gate electrode 2850 may be covered with a carbon layer. Upper surfaces and side surfaces of the carbon layer 2840 and the gate electrode 2850 may be parallel to an upper surface and side surfaces of the gate insulating layer 2830. A stack including the sequentially stacked gate insulating layer 2830, the carbon layer 2840, and the gate electrode 2850 may be referred to as a gate stack GS1.

FIG. 30 shows a cross-sectional view taken along line 30-30′ of FIG. 28.

Referring to FIG. 30, the semiconductor layer 2820 is formed on one surface of the substrate 2810. The gate insulating layer 2830, the carbon layer 2840, and the gate electrode 2850 are sequentially stacked on a partial region of an upper surface of the semiconductor layer 2820. A layer structure including the sequentially stacked semiconductor layer 2820, the gate insulating layer 2830, the carbon layer 2840, and the gate electrode 2850 may correspond to one of the layer structures 100, 300, 500, 700, and 1000 shown in at least FIGS. 1, 3, 5, 7, 10, etc.

In the semiconductor layer 2820, a left part and a right part of the gate stack GS1 may be doped with the same dopant. In an example, the dopant may include an N-type or P-type impurity. Depending on the dopant, the second electronic device 2800 may be an N-type device or a P-type device. One of a left part and a right part of the semiconductor layer 2820 may be a source region, and the other may be a drain region. In the semiconductor layer 2820, a region under the gate stack GS1 may be a channel. The second electronic device 2800 may be a top gate FinFET in which the gate electrode 2850 is arranged above the channel.

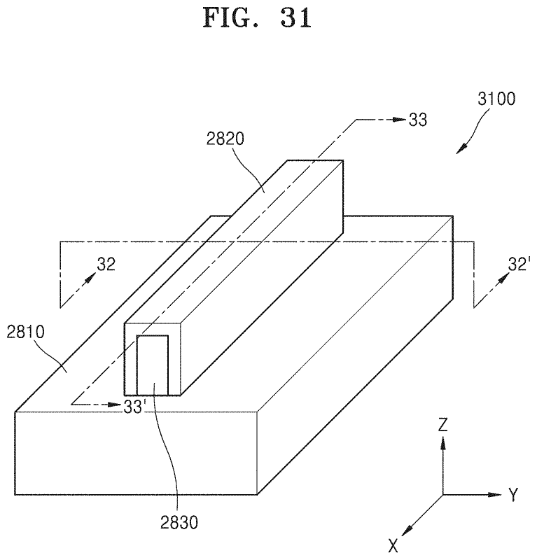

FIG. 31 shows a third electronic device 3100 including a layer structure according to an embodiment.

Referring to FIG. 31, the semiconductor layer 2820 is arranged on the substrate 2810 in a direction parallel to the X-axis. An aspect ratio of the semiconductor layer 2820 may be greater than 1 (e.g., greater than 1 and less than or equal to 5), but may be equal to or less than 1.

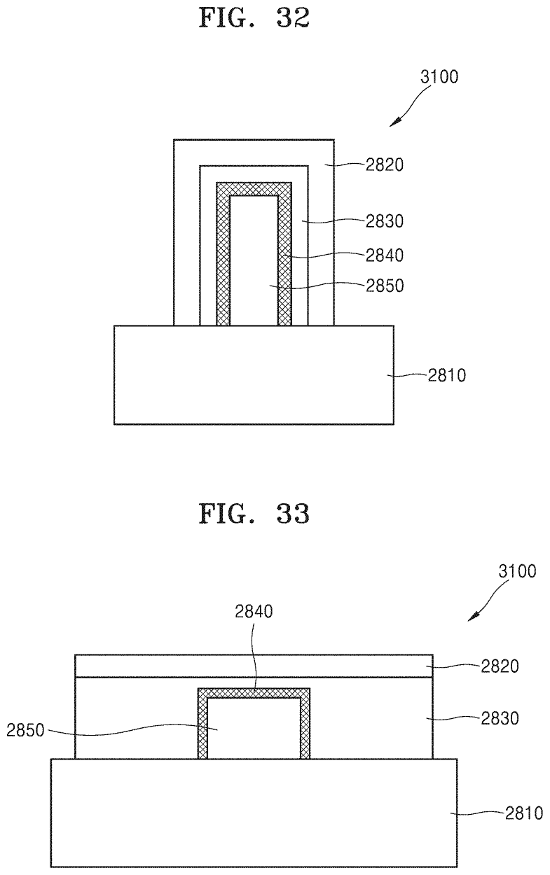

FIG. 32 shows a cross-sectional view taken along line 32-32′ of FIG. 31.

Referring to FIG. 32, the gate electrode 2850 is formed on the substrate 2810. An aspect ratio of the gate electrode 2850 may be greater than 1 (e.g., greater than 1 and less than or equal to 5), may be 1, or may be less than 1. Both side surfaces and an upper surface of the gate electrode 2850 are covered with the carbon layer 2840. A thickness of the carbon layer 2840 on a surface of the gate electrode 2850 may be constant or substantially constant. An upper surface and both side surfaces of the carbon layer 2840 may be parallel to an upper surface and both side surfaces of the gate electrode 2850. The gate insulating layer 2830 and the semiconductor layer 2820 are sequentially formed on the upper surface and both side surfaces of the carbon layer 2840. The semiconductor layer 2820 may be formed to have greater thickness than the gate insulating layer 2830. A region of the semiconductor layer 2820 in contact with the gate insulating layer 2830 may be a channel. A layer structure in which the semiconductor layer 2820, the gate insulating layer 2830, the carbon layer 2840, and the gate electrode 2850 are sequentially stacked may correspond to one of the layer structures 100, 300, 500, 700, and 1000 shown in at least FIGS. 1, 3, 5, 7, 10, etc.

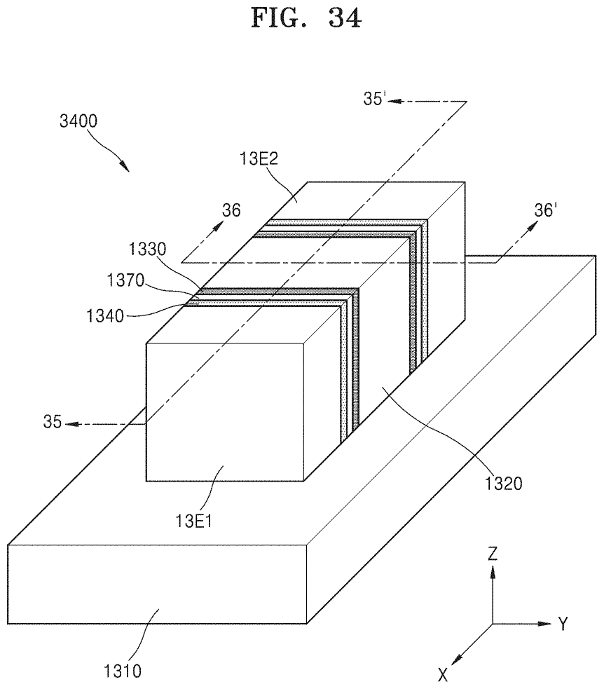

FIG. 33 shows a cross-sectional view taken along line 33-33′ of FIG. 31.

Referring to FIG. 33, the gate electrode 2850 is arranged on a partial region of the upper surface of the substrate 2810. An upper surface and both side surfaces of the gate electrode 2850 are covered with the carbon layer 2840. The carbon layer 2840 may be in direct contact with the upper surface and both side surfaces of the gate electrode 2850. The gate insulating layer 2830 covering the gate electrode 2850 and the carbon layer 2840 is formed on the upper surface of the substrate 2810. The gate insulating layer 2830 may be formed to cover the upper surface of the substrate 2810 around the gate electrode 2850 and to cover the upper surface and both side surfaces of the carbon layer 2840. An upper surface of the gate insulating layer 2830 is formed to be flat. A portion of the gate insulating layer 2830 formed on the upper surface of the gate electrode 2850 may be formed to have a constant thickness. A portion of the gate insulating layer 2830 formed on both sides of the gate electrode 2850 may have a thickness greater than the portion formed on the upper surface of the gate electrode 2850. The semiconductor layer 2820 is formed on the gate insulating layer 2830. The semiconductor layer 2820 may be formed to cover an entire upper surface of the gate insulating layer 2830. A portion of the semiconductor layer 2820 corresponding to the upper surface of the gate electrode 2850 may include a channel. In the semiconductor layer 2820, a left part and a right part of the gate electrode 2850 may be regions doped with an N-type or P-type dopant. One of the left part and the right part may be a source region, and the other may be a drain region. The semiconductor layer 2820 including a channel is arranged on the gate electrode 2850. That is, the semiconductor layer 2820 may be arranged to face the gate electrode 2850 with the gate insulating layer 2830 therebetween. The semiconductor layer 2820 may be formed to cover the entire upper surface of the gate insulating layer 2830. The third electronic device 3100 may be a bottom-gate FinFET in which a gate electrode 2850 is arranged under a channel.

FIG. 34 is a three-dimensional view of a fourth electronic device 3400 including a layer structure according to an embodiment.

Referring to FIG. 34, a first electrode 13E1, a gate electrode 1320, and a second electrode 13E2 are sequentially aligned on a substrate 1310 in a direction parallel to the X-axis. The substrate 1310 may include an insulating substrate. In one example, the substrate 1310 may be a semiconductor substrate having an insulating layer on a surface thereof. In this case, the semiconductor substrate may include, for example, Si, Ge, SiGe, or a Group III-V semiconductor material. The substrate 1310 may include, for example, a silicon substrate having a silicon oxide on a surface thereof, but is not limited thereto. Each of the first electrode 13E1, the gate electrode 1320, and the second electrode 13E2 may have an aspect ratio of 1 or more, but may be less than 1. The first and second electrodes 13E1 and 13E2 may be N-type or P-type semiconductor layers. In one example, a material of the first and second electrodes 13E1 and 13E2 may be the same as the semiconductor layer used as the substrate 102 of FIG. 1. The gate electrode 1320 may be a metal gate electrode. In one example, the gate electrode 1320, as a single layer, may include a first metal layer 108 described with reference to FIGS. 1 to 23. In one example, the gate electrode 1320 may include the sequentially stacked first and second metal layers 108 and 708 described with reference to FIGS. 1 to 23.

A channel layer 1340, a gate insulating layer 1370, and a conductive carbon layer 1330 are sequentially formed between the first electrode 13E1 and the gate electrode 1320 in a direction from the first electrode 13E1 to the gate electrode 1320. The carbon layer 1330, the gate insulating layer 1370, and the channel layer 1340 are sequentially formed between the gate electrode 1320 and the second electrode 13E2 in a direction from the gate electrode 1320 to the second electrode 13E2. The channel layer 1340 may include a semiconductor layer doped with a P-type or N-type impurity. In one example, a semiconductor material used as the channel layer 1340 may be the same as a material of the first and second electrodes 13E1 and 13E2. In one example, the material and role of the carbon layer 1330 may be the same as those of the first carbon layer 106 of the layer structures described with reference to FIGS. 1 to 23. One of the first and second electrodes 13E1 and 13E2 may be a source electrode, and the other may be a drain electrode. A height of the first and second electrodes 13E1 and 13E2 in the direction perpendicular to the substrate 1310 (the Z-axis direction) may be the same as a height of the gate electrode 1320, but is not limited thereto.

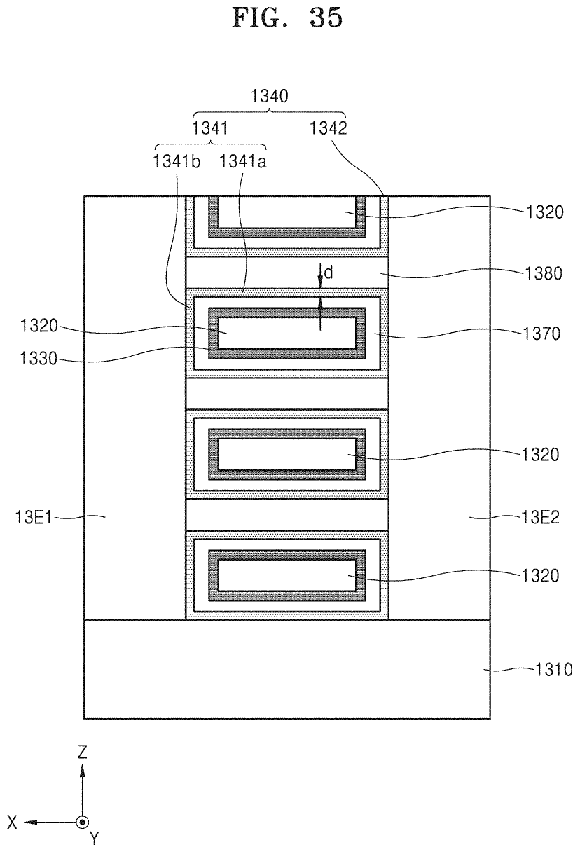

FIG. 35 shows a cross-sectional view taken along line 35-35′ of FIG. 34.

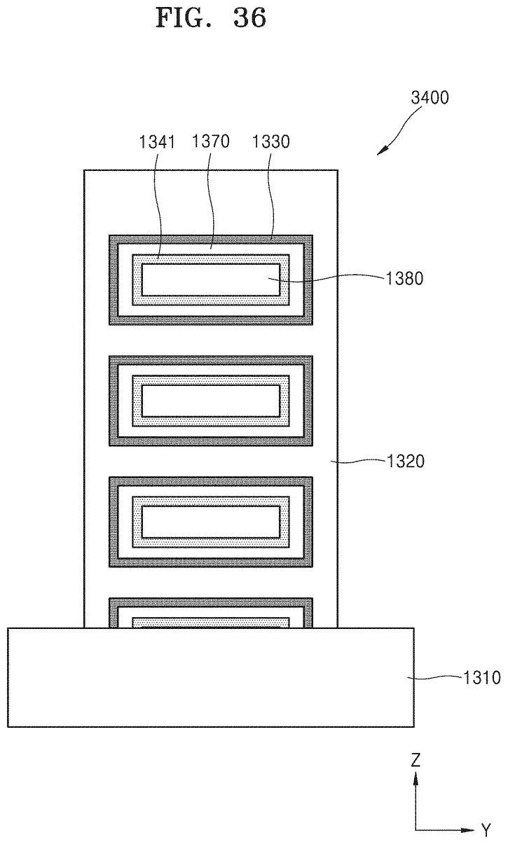

FIG. 36 shows a cross-sectional view taken along line 36-36′ of FIG. 34.

The cross section shown in FIG. 35 may indicate a first cross section cut from the first electrode 13E1 to the second electrode 13E2 (the X-direction in the drawing) in a direction perpendicular to the substrate 1310 (the Z-direction in the drawing). The cross-section shown in FIG. 36 may indicate a second cross-section cut across (the Y-direction in the drawing) between the first electrode 13E1 and the second electrode 13E2 in a direction perpendicular to the substrate 1310 (the Z-direction in the drawing). Here, because the substrate 1310 may not be completely planar, the vertical direction may include a substantially vertical direction as well as a general vertical direction. In the present specification, the definitions described above for the first cross-section and the second cross-section are jointly used.

Referring to FIG. 35, the channel layer 1340 may include a first channel 1341 having a hollow closed-type cross-sectional structure in the first cross-section. The hollow closed-type cross-sectional structure may include, for example, a closed-loop shape including a square, circular, oval, or irregular figure, etc. The first channel 1341 may include, for example, a sheet portion 1341a connected across the first electrode 13E1 and the second electrode 13E2, and a contact portion 1341b that contacts the first electrode 13E1 and the second electrode 13E2. The sheet portion 1341a is parallel or substantially parallel to the substrate 1310, and thus, may be referred to as a horizontal portion. The contact portion 1341b may be referred to as a vertical portion because it is perpendicular or substantially perpendicular to the substrate 1310. The first channel 1341 may include two sheet portions 1341a. The contact portion 1341b may support the two sheet portions 1341a and define a gap between the two sheet portions 1341a.

A plurality of first channels 1341 may be provided, and the first channels 1341 may be arranged to be separated from each other in a direction perpendicular to the substrate 1310 (the Z-direction). In other words, the adjacent first channel 1341 and the first channel 1341 may be arranged separately from each other.

Meanwhile, the channel layer 1340 may include a second channel 1342 having an open cross-sectional structure or a sheet-like structure at least one of an upper end and a lower end in the first cross-section. The channel layer 1340 may be connected between the first electrode 13E1 and the second electrode 13E2 to perform as a passage for flowing a current between the first electrode 13E1 and the second electrode 13E2. The channel layer 1340 may directly contact the first electrode 13E1 and the second electrode 13E2. In one example, the channel layer 1340 may be connected to the first electrode 13E1 and the second electrode 13E2 through another medium.

Because the first channel 1341 has a hollow closed-type cross-sectional structure, the first channel 1341 may be in surface contact with the first electrode 13E1 and the second electrode 13E2, and a contact area may be increased by adjusting a thickness of the hollow. That is, a contact area between the first channel 1341 and the first electrode 13E1 and a contact area between the first channel 1341 and the second electrode 13E2 may be adjusted by adjusting a length of the contact portion 1341b of the first channel 1341. For example, a length of the contact portion 1341b may have a range of about 100 nm or less. In one example, the length of the contact portion 1341b may be in a range of less than or equal to 50 nm. In one example, the length of the contact portion 1341b may be in a range of about 20 nm or less. In one example, the length of the contact portion 1341b may be in a range of about 10 nm or less.

In one example, a thickness d of the sheet portion 1341a connected between the first electrode 13E1 and the second electrode 13E2 in the first channel 1341 may be about 20 nm or less. In one example, a length of the sheet portion 1341a of the first channel 1341 may be about 10 nm or less. In one example, the thickness d of the sheet portion 1341a of the first channel 1341 may be about 5 nm or less. In one example, the thickness d of the sheet portion 1341a of the first channel 1341 may be about 1 nm or less. In one example, a distance between the first electrode 13E1 and the second electrode 13E2 may be in the range of about 100 nm or less. In one example, the distance between the first electrode 13E1 and the second electrode 13E2 may be in a range of about 50 nm or less. In one example, the distance between the first electrode 13E1 and the second electrode 13E2 may be in the range of about 20 nm or less.

A gate insulating layer 1370 may be arranged on inner surfaces of the first channel 1341 and the second channel 1342. The gate insulating layer 1370 may be formed to cover entire inner surfaces of the first and second channels 1341 and 1342. The carbon layer 1330 may be arranged on an inner surface of the gate insulating layer 1370. The carbon layer 1330 may cover the entire inner surface of the gate insulating layer 1370. A material of the gate insulating layer 1370 may be the same as that of the insulating layer 104 of FIG. 1. The gate electrode 1320 may be arranged inside the carbon layer 1330. In the first cross-section, the carbon layer 1330 may be arranged inside the first channel 1341, and the gate electrode 1320 may be arranged inside the carbon layer 1330. The inside of the carbon layer 1330 may be filled with the gate electrode 1320. Spaces between the carbon layer 1330 and the first channel 1341 and a space between the carbon layer 1330 and the second channel 1342 may be filled with the gate insulating layer 1370 during a manufacturing process. In one example, the gate insulating layer 1370 may directly contact the first and second channels 1341 and 1342 and the carbon layer 1330.

In the first cross-section, the first channel 1341 and the gate insulating layer 1370 may have a structure that surrounds the entire gate electrode 1320. Accordingly, the gate electrode 1320 may correspond to the entire inner surface of the first channel 1341 with the carbon layer 1330 and the gate insulating layer 1370 therebetween. A layer structure including the channel layer 1340, the gate insulating layer 1370, the carbon layer 1330, and the gate electrode 1320 sequentially stacked in a given direction may correspond to the layer structures described with reference to FIGS. 1 to 23, for example, correspond to the first layer structure 100 of FIG. 1. Accordingly, the fourth electronic device 3400 may also have the same characteristic as the first layer structure 100 of FIG. 1 including the carbon layer 106.

Although not shown, in an example, a buffer layer may further be arranged between the channel layer 1340 and the gate insulating layer 1370.

An insulating layer 1380 may further be arranged between the adjacent first channels 1341 and between the first and second channels 1341 and 1342. The insulating layer 1380 may be arranged across the first electrode 13E1 and the second electrode 13E2. The insulating layer 1380 may directly contact the first electrode 13E1 and the second electrode 13E2. The insulating layer 1380 insulates the channel and the channel, and may function as a supporting layer for depositing the channel in a manufacturing process. In one example, the insulating layer 1380 may have a thickness in a range of greater than about 0 nm and less than or equal to about 100 nm. In one example, the insulating layer 1380 may have a thickness in a range of greater than about 0 nm and less than or equal to about 20 nm. The insulating layer 1380 may include at least one of low-doped silicon, SiO₂, Al₂O₃, HfO₂, or Si₃N₄.

In the present embodiment, the first channel 1341 may have a hollow closed-type cross-sectional structure, and may be connected with a multi-bridge structure between the first electrode 13E1 and the second electrode 13E2. On the substrate 1310, the first electrode 13E1 and the second electrode 13E2 are arranged to be separated from each other in a first direction, and the first channels 1341 are arranged between the first electrode 13E1 and the second electrode 13E2 to be separated from each other in a second direction perpendicular to the substrate 1310. The first direction may be an X-axis direction, and the second direction may be a Z-axis direction.

Referring to FIG. 36, the channel layer 1340 may include the first channel 1341 having a hollow closed-type cross-sectional structure in the second cross-section. A plurality of first channels 1341 may be provided and arranged to be separated from each other. The gate insulating layer 1370 may be arranged between the first channel 1341 and the carbon layer 1330, and the gate electrode 1320 may be provided to surround the carbon layer 1330 around the carbon layer 1330. In the second cross-section, the first channel 1341 is arranged to be separated from each other in a height direction of the fourth electronic device 3400, that is, in a direction perpendicular to the substrate 1310 (the Z-axis direction), the gate insulating layer 1370 and the carbon layer 1330 may be sequentially arranged on an outer side of the first channel 1341, and the gate insulating layer 1370 and the gate electrode 1320 may be arranged in the form of surrounding the first channel 1341. That is, the gate insulating layer 1370 surrounds the entire first channel 1341. In addition, the gate electrode 1320 surrounds the entire side of the first channel 1341. Therefore, the present embodiment may have a so-called all around gate structure. The first channel 1341 in the first cross-section and the first channel 1341 in the second cross-section may be alternately arranged in a direction perpendicular to the substrate 1310. The insulating layer 1380 may be arranged inside the first channel 1341. In one example, the inside of the first channel 1341 may be filled with an insulating layer 1380.

As shown in FIG. 36, the carbon layer 1330 may be in contact with the gate insulating layer 1370 and the carbon layer 1330 may be formed to have a shape surrounding the first channel 1341 with a closed path. In addition, the gate electrode 1320 may be separated from the first channel layer 1341 with the carbon layer 1330 and the gate insulating layer 1370 therebetween. The gate electrode 1320 may be formed to have a shape surrounding the first channel 1341 with a closed path. Because the carbon layer 1330 is arranged between the gate insulating layer 1370 and the gate electrode 1320, diffusion of a material that deteriorates leakage current characteristics from the gate electrode 1320 to the gate insulating layer 1370 is limited and/or prevented, and thus, a leakage current through the insulating layer 1370 may be limited and/or suppressed. In one example, the carbon layer 1330 may also be present on an upper surface and side surfaces of the gate electrode 1320.

In addition, the fourth electronic device 3400 according to an embodiment, as a field effect transistor, includes a multi-bridge type channel, thereby suppressing a short channel effect and effectively reducing a channel thickness and a channel length. In addition, the fourth electronic device 3400 has an ultrasmall size and has excellent electrical performance, thus, it is suitable for being applied to an integrated circuit device having a high degree of integration.

The electronic devices according to the embodiments described above may constitute a transistor constituting a digital circuit or an analog circuit. In some embodiments, the electronic device according to the embodiments may be used as a high voltage transistor or a low voltage transistor. For example, the electronic device according to the embodiments may constitute a high voltage transistor constituting a peripheral circuit of a flash memory device that is a nonvolatile memory device operating at a high voltage or an electrically erasable and programmable read only memory (EEPROM) device. Alternatively, the electronic device according to the embodiments may constitute a transistor to be included in an IC device for a liquid crystal display (LCD) requiring an operating voltage of 10 V or greater, for example, an operating voltage of 20 V to 30 V, or an IC chip used in a plasma display panel (PDP) requiring an operating voltage of 100 V.

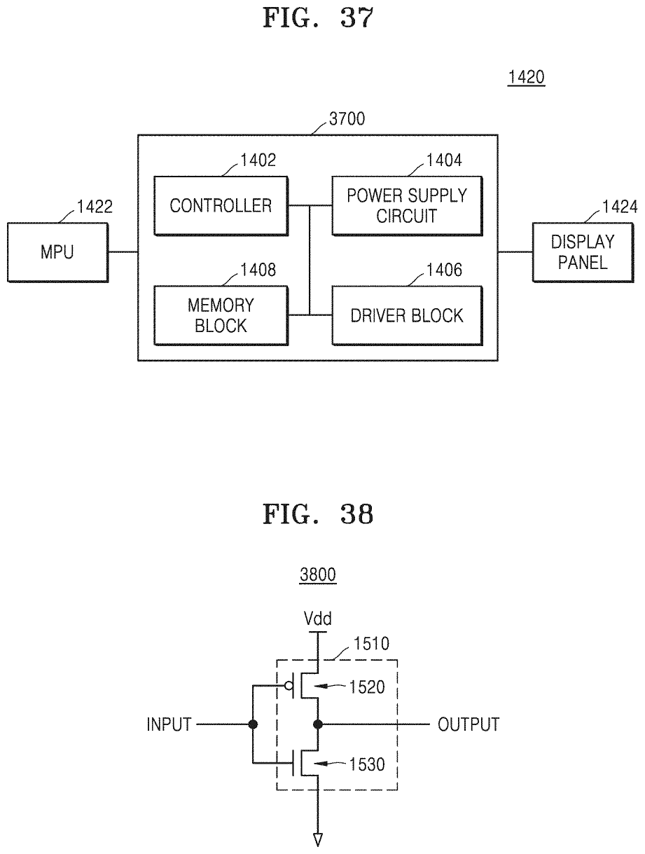

FIG. 37 is a schematic block diagram of a display driver IC (DDI) 3700 and a display apparatus 1420 including the DDI 3700 according to an embodiment.

Referring to FIG. 37, the DDI 3700 may include a controller 1402, a power supply circuit 1404, a driver block 1406, and a memory block 1408. The controller 1402 receives and decodes a command applied from a main processing unit (MPU) 1422, and controls each block of the DDI 3700 to implement an operation according to the command. The power supply circuit unit 1404 generates a driving voltage in response to the control of the control unit 1402. The driver block 1406 drives a display panel 1424 using the driving voltage generated by the power supply circuit unit 1404 in response to the control of the controller 1402. The display panel 1424 may be a liquid crystal display panel or a plasma display panel. The memory block 1408 is a block for temporarily storing commands input to the controller 1402 or control signals output from the controller 1402, or for storing necessary data, and may include a memory, such as RAM or ROM. The power supply circuit unit 1404 and the driver block 1406 may include the electronic device according to the embodiment described above.

FIG. 38 is a circuit diagram of a complementary metal-oxide semiconductor (CMOS) inverter 3800 according to an embodiment.

The CMOS inverter 3800 includes a CMOS transistor 1510. The CMOS transistor 1510 includes a PMOS transistor 1520 and an NMOS transistor 1530 connected between a power terminal Vdd and a ground terminal. The CMOS transistor 1510 may include the electronic device according to the embodiment described above.

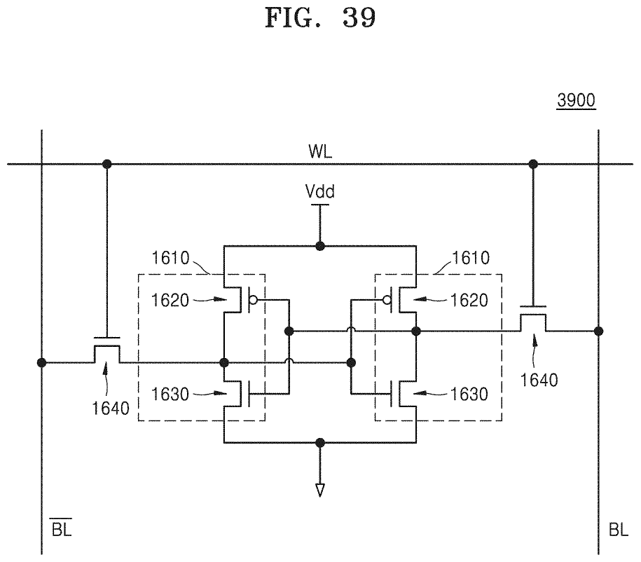

FIG. 39 is a circuit diagram of a CMOS SRAM device 3900 according to an embodiment.

The CMOS SRAM device 3900 includes a pair of driving transistors 1610. The pair of driving transistors 1610 includes a PMOS transistor 1620 and an NMOS transistor 1630 connected between a power terminal Vdd and a ground terminal, respectively. The CMOS SRAM device 3900 may further include a pair of transmission transistors 1640. A source of the transmission transistor 1640 is cross-connected to a common node of the PMOS transistor 1620 and the NMOS transistor 1630 constituting the driving transistor 1610. A power terminal Vdd is connected to a source of the PMOS transistor 1620, and a ground terminal is connected to the source of the NMOS transistor 1630. A word line WL may be connected to a gate of the pair of transmission transistors 1640, and a bit line BL and an inverted bit line may be connected to a drain of each of the pair of transmission transistors 1640, respectively.

At least one of the driving transistor 1610 and the transmission transistor 1640 of the CMOS SRAM device 3900 may include the electronic device according to the embodiment described above.

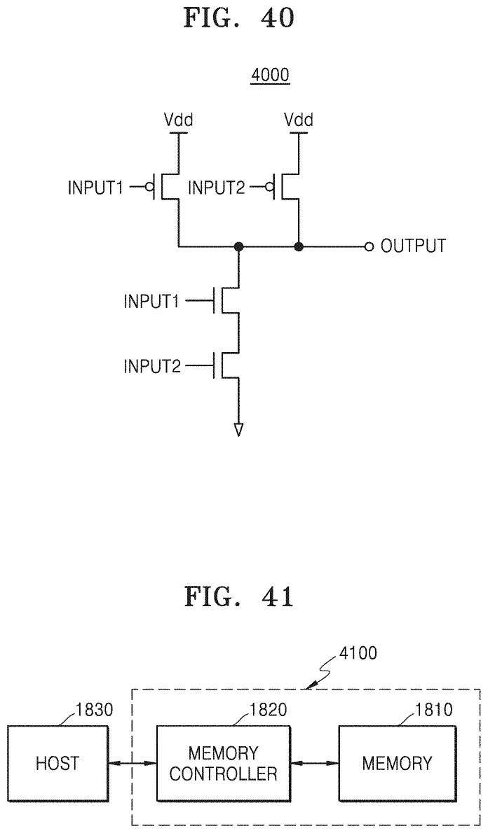

FIG. 40 is a circuit diagram of a CMOS NAND circuit 4000 according to an embodiment.

The CMOS NAND circuit 4000 includes a pair of CMOS transistors to which different input signals are transmitted. The CMOS NAND circuit 4000 may include the electronic device according to the embodiment described above.

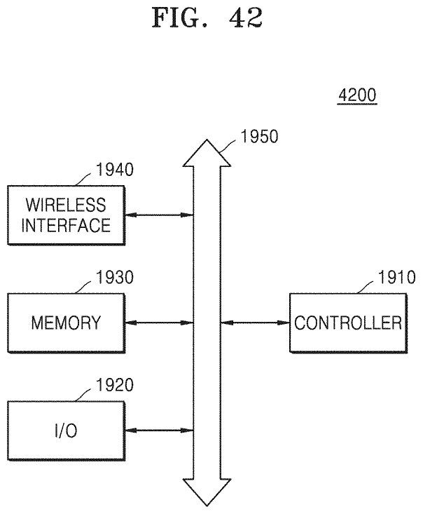

FIG. 41 is a block diagram illustrating an electronic system 4100 according to an embodiment.

The electronic system 4100 includes a memory 1810 and a memory controller 1820. The memory controller 1820 may control the memory 1810 to read data from and/or write data to the memory 1810 in response to a request from the host 1830. At least one of the memory 1810 and the memory controller 1820 may include the electronic device according to the embodiment described above.

FIG. 42 is a block diagram of an electronic system 4200 according to an embodiment.

The electronic system 4200 may constitute a wireless communication device or a device capable of transmitting and/or receiving information in a wireless environment. The electronic system 4200 includes a controller 1910, an input/output device (I/O) 1920, a memory 1930, and a wireless interface 1940, and these components are interconnected to each other through a bus 1950.

The controller 1910 may include at least one of a microprocessor, a digital signal processor, or a processing device similar thereto. The input/output device 1920 may include at least one of a keypad, a keyboard, and a display. The memory 1930 may be used to store instructions executed by controller 1910. For example, the memory 1930 may be used to store user data. The electronic system 4200 may use the wireless interface 1940 to transmit/receive data through a wireless communication network. The wireless interface 1940 may include an antenna and/or a wireless transceiver. In some embodiments, the electronic system 4200 may be used in a communication interface protocol of a variety of communication systems, for example, code division multiple access (CDMA), global system for mobile communications (GSM), north American digital cellular (NADC), extended-time division multiple access (E-TDMA), and/or wide band code division multiple access (WCDMA). The electronic system 4200, as a field effect transistor, may include the electronic device according to the embodiment described above.

An electronic device including a layer structure according to an embodiment may exhibit high electrical performance with an ultrasmall structure, and thus, may be applied to an integrated circuit device, and may realize miniaturization, low power, and high performance.

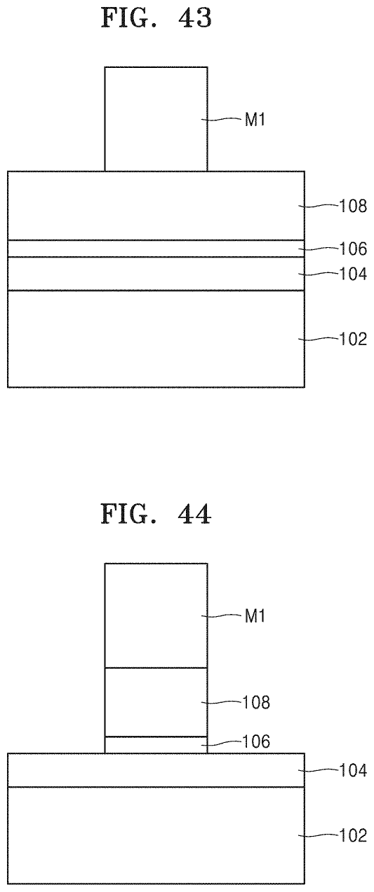

Next, a method of manufacturing a layer structure including a metal layer and a carbon layer according to an embodiment will be described with reference to FIGS. 43 to 47. Like reference numerals are used to indicate the same members as those mentioned in the layer structures described above, and descriptions thereof will be omitted.

First, referring to FIG. 43, an insulating layer 104 is formed on a substrate 102, and a first carbon layer 106 is formed on the insulating layer 104. In one example, the first carbon layer 106 may be formed by using a plasma enhanced chemical vapor deposition (PECVD) method, but is not limited thereto. In one example, after the first carbon layer 106 is formed outside, it may be transferred onto the insulating layer 104. Next, a first metal layer 108 is formed on the first carbon layer 106. A metal layer including a metal different from the first metal layer 108 may further be formed on the first metal layer 108. A mask M1 is formed on a partial region of the first metal layer 108. For example, the mask M1 may include a photoresist layer. A specific region may be defined in the first metal layer 108 and the first carbon layer 106 by the mask M1.

After the mask M1 is formed, the first metal layer 108 and the first carbon layer 106 around the mask M1 are sequentially etched. The etching may be performed until the insulating layer 104 is exposed.

FIG. 44 shows a result after the etching is completed.

Referring to FIG. 44, the first carbon layer 106 and the first metal layer 108 are removed on the insulating layer 104 around the mask M1 by the etching, and an upper surface of the insulating layer 104 around the mask M1 is exposed. After the etching, the mask M1 is removed.

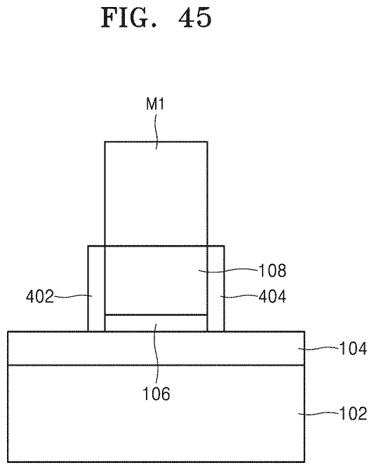

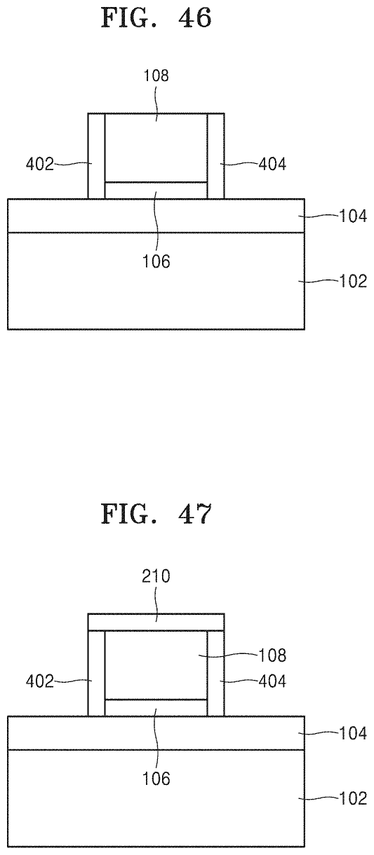

FIG. 45 shows a case in which third and fourth carbon layers 402 and 404 are additionally formed on side surfaces of the first metal layer 108 while the mask M1 is maintained in FIG. 44. The third and fourth carbon layers 402 and 404 may be formed to cover the entire both side surfaces of the first metal layer 108 and both side surfaces of the first carbon layer 106. In one example, the third and fourth carbon layers 402 and 404 may be formed by using a PECVD method, but the present disclosure is not limited thereto. After the third and fourth carbon layers 402 and 404 are formed, the mask M1 may be removed. FIG. 46 shows a result of removing the mask M1 in FIG. 45.

In FIG. 46, a carbon layer may also be formed on the upper surface of the first metal layer 108 as shown in FIG. 47.

Referring to FIG. 47, a second carbon layer 210 may be formed on the upper surface of the first metal layer 108 exposed by removing the mask M1 of FIG. 45. The second carbon layer 210 may be formed to cover the entire upper surface of the first metal layer 108 and entire upper surfaces of the third and fourth carbon layers 402 and 404. In one example, the second carbon layer 210 may be formed by using a PECVD method, but is not limited thereto.

In an embodiment, in FIG. 46, a second metal layer 708 (refer to FIG. 16) may be formed on the first metal layer 108, which may be the layer structure of FIG. 16, and carbon layers may be formed on both sides and/or upper surfaces of the formed second metal layer 708, which may be the layer structure of FIG. 17 or FIG. 15. In one embodiment, the second metal layer 708 may be formed on the second carbon layer 210 of FIG. 47, and carbon layers may be formed on both sides and/or upper surfaces of the formed second metal layer 708, which may be the layer structure of FIG. 19 or FIG. 20. In this way, various layer structures described above may be formed by appropriately combining the formation positions of the metal layer and the carbon layer.

The disclosed layer structure includes a carbon layer (e.g., graphene) between a metal layer, which may be used as a gate electrode and an insulating layer, which may be used as a gate insulating layer. Because the carbon layer is provided, a case in which a current (electrons) flowing through the metal layer is scattered on a surface of the metal layer may be reduced or prevented. Accordingly, the specific resistance of the metal layer capped with the carbon layer may be improved.

In addition, because the carbon layer is provided, diffusion of a material (e.g., ions) from the metal layer to the insulating layer may be reduced or prevented, and thus, the deterioration of a leakage current characteristic of the insulating layer may be limited and/or prevented. That is, the carbon layer may serve as a diffusion barrier for metal or the like.

In addition, because the water contact angle of the carbon layer is 80° or more and indicates a hydrophobic property, oxidation due to moisture may be prevented. That is, the carbon layer may serve as a barrier to oxygen.

In addition, because the carbon layer is provided, it is possible to control the work function of the metal layer.

The characteristics of the disclosed layer structure may be directly applied to an electronic device (e.g., a field effect transistor) including the disclosed layer structure and an electronic apparatus including the electronic device, and thus, the operational characteristics of the electronic device and the electronic apparatus may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of inventive concepts as defined by the following claims.

What is claimed is:

1. A layer structure comprising:
a semiconductor layer;
an insulating layer on one surface of the semiconductor layer;
a first metal layer facing the semiconductor layer with the insulating layer therebetween; and
a first carbon layer between the insulating layer and the first metal layer, the first carbon layer being in contact with a first surface of the first metal layer, and the first carbon layer being conductive.

2. The layer structure of claim 1,
wherein the first metal layer is above the semiconductor layer or the first metal layer is below the semiconductor layer.

3. The layer structure of claim 1, further comprising:
a second metal layer on the first metal layer.

4. The layer structure of claim 3,
wherein the first carbon layer extends onto a surface of the second metal layer.

5. The layer structure of claim 4,
wherein the first carbon layer extends between the first metal layer and the second metal layer.

6. The layer structure of claim 5,
wherein the first carbon layer covers an upper surface of the second metal layer and both side surfaces of the second metal layer.

7. The layer structure of claim 1,
wherein the first carbon layer is in direct contact with the insulating layer.

8. The layer structure of claim 1,
wherein the first carbon layer extends onto a second surface of the first metal layer, and
the second surface of the first metal layer is different from the first surface of the first metal layer.

9. The layer structure of claim 8,
wherein the first carbon layer covers a bottom surface and both side surfaces of the first metal layer.

10. The layer structure of claim 1,
wherein the first carbon layer covers four sides around the first metal layer.

11. The layer structure of claim 1,
wherein the first carbon layer includes an sp2 bond and an sp3 bond, and
a ratio of sp3 bonding to sp2 bonding in the first carbon layer is about 0 to 1.

12. The layer structure of claim 1,
wherein the first carbon layer includes a graphene layer.

13. The layer structure of claim 12,
wherein the graphene layer includes a nanocrystalline graphene layer.

14. The layer structure of claim 13,
wherein a size of the nanocrystalline graphene layer is in a range from about 0.5 nm to about 150 nm.

15. The layer structure of claim 1,
wherein a water contact angle of the first carbon layer is in a range from about 80° to about 110°.

16. The layer structure of claim 1,
wherein an aspect ratio of the semiconductor layer is 1 or more.

17. The layer structure of claim 1,
wherein an aspect ratio of the first metal layer is 1 or more.

18. The layer structure of claim 1,
wherein the first metal layer includes a one-component metal or a two-component metal.

19. An electronic device comprising:
the layer structure of claim 1, wherein
the semiconductor layer is a substrate,
the substrate includes a first doped region and a second doped region separated from each other;
the insulating layer is a gate insulating layer on the substrate between the first doped region and the second doped region;
a first carbon layer is on the gate insulating layer; and
the first metal layer is a metal gate electrode on the first carbon layer.

20. The electronic device of claim 19,
wherein the first doped region and the second doped region include a P-type or N-type dopant.

21. An electronic apparatus comprising:
the electronic device of claim 19, wherein
the electronic device is configured to regulate a flow of an electrical signal.

22. A method of manufacturing a layer structure, the method comprising:
forming an insulating layer on a semiconductor layer;
forming a first metal layer on the insulating layer; and
forming a conductive carbon layer in contact with at least a first surface of the first metal layer,
wherein at least a portion of the conductive carbon layer is formed between the insulating layer and the first metal layer.

23. The method of claim 22,
wherein the forming the conductive carbon layer is performed using a PECVD method.

24. The method of claim 22,
wherein the forming the conductive carbon layer includes at least one of:
forming a first carbon layer in contact with a bottom surface of the first metal layer facing the insulating layer;
forming a second carbon layer on a side surface of the first metal layer; and
forming a third carbon layer on an upper surface of the first metal layer.

25. The method of claim 22, further comprising:
forming a second metal layer on the first metal layer.

26. The method of claim 25,
wherein the forming the conductive carbon layer further includes forming a carbon layer on an outer surface of the second metal layer.

27. The method of claim 22,
wherein the forming the conductive carbon layer includes one of:
directly forming a graphene layer in contact with the first surface of the first metal layer; and
transferring a graphene layer on the insulating layer.

28. The method of claim 27,
wherein the graphene layer includes a nanocrystalline graphene layer.

29. The method of claim 25,
wherein the conductive carbon layer has a ratio of sp3 bonds to sp2 bonds in a range of about 0 to about 1.
